(19) United States
(12) Patent Application Publication
(10) Pub. No.: US 2010/0229069 A1
(43) Pub. Date: Sep. 9, 2010

(54) DRIVE DEVICE, CONTENT REPRODUCTION DEVICE, RECORDING DEVICE, DATA READOUT METHOD, PROGRAM, RECORDING MEDIUM, AND INTEGRATED CIRCUIT

(76) Inventors: Takahiro Yamaguchi, Osaka (JP); Masaya Yamamoto, Osaka (JP); Makoto Usui, Osaka (JP); Shunji Harada, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/673,819

(22) PCT Filed: Jun. 23, 2009
(86) PCT No.: PCT/JP2009/002846

§ 371 Date: Mar. 16, 2010

(30) Foreign Application Priority Data
Jul. 1, 2008 (JP) 2008-172590

(51) Int. Cl. G06F 12/14; H03M 13/05; G06F 11/10

(52) U.S. Cl. 714/752; 713/189; 714/E11.032

(57) ABSTRACT

A drive device is provided to promote copyright protection by preventing playback of copied contents, even if unique identification information on a recording medium, used to generate title keys for decrypting encrypted contents, is revealed, and the contents are independently encrypted and copied using this identification information. Identification information unique to a recording medium 103 and used to generate title keys is recorded thereon, along with a signature for the identification information issued by a certificate authority terminal device 101. Before decryption and playback of the encrypted contents, a drive in a playback device 104 performs signature verification. When verification fails, the drive does not output the identification information. A program for playback in the playback device 104 therefore cannot generate a decryption key and fails to decrypt and play back the encrypted contents. The signature is not output externally. Therefore, an unauthorized individual cannot copy the recording medium 103.

### TECHNICAL FIELD

The present invention relates to copyright protection of digital contents, and in particular to technology to suppress unauthorized copying of digital contents recorded on a recording medium.

### BACKGROUND ART

In recent years, digital contents (hereinafter, simply “contents”), wherein copyrighted works such as movies and music are digitalized, have become widely distributed. As these contents are easy to duplicate, and as the quality of copies does not degrade, copyright protection technology is extremely important. For copyright protection of a recording medium such as a Digital Versatile Disc (DVD), which is one representative medium for content distribution, identification information identifying the recording medium is recorded in a recording area whose data normally cannot be duplicated. This identification information is used as part of an encryption key (see Non-Patent Literature 1) to prevent unauthorized copying of the recording medium (see Patent Literature 1). In this structure, when a copy of the recording medium is attempted, while the data of the contents and the like are copied from the original recording medium to the target recording medium, the identification information unique to the recording medium is not copied, and thus the identification information on the original disc and the identification information on the target disc differ. Accordingly, when playback of the contents on the target recording medium is attempted, the decryption key cannot be recovered with the identification information recorded on the target recording medium. Therefore, it is possible to prevent unauthorized decryption of encrypted contents.

### CITATION LIST

### Patent Literature

[Patent Literature 1]

Japanese Patent Application Publication No. 2005-196926

### Non-Patent Literature

[Non-Patent Literature 1]

“Digital Signatures and Encryption”, trans. Shinichiro YAMADA, Pearson Education

### SUMMARY OF INVENTION

### Technical Problem

It can be assumed, however, that unauthorized individuals may acquire a device that can write arbitrary identification information on a recording medium on which identification information has not yet been recorded and use the device to write, on the target recording medium, the same identification information as that on the original recording medium. With the above-described prior art, it is impossible to avoid duplication of a recording medium by such a device that can write identification information. In other words, during the process to play back contents on a playback device, the identification information on a recording medium can somehow be acquired, and using this identification information and an independent encoder, the contents and the identification information can be encrypted and recorded on a recording medium to produce an unauthorized copy. This unauthorized copy of the recording medium can be played back on a normal playback device just as the original, authentic recording medium.

In view of the above problems, an aim of the present invention is to provide a drive device, contents playback device, recording device, data reading method, program, recording medium, and integrated circuit that promote copyright protection by preventing playback of copied contents even if unique identification information on a recording medium is revealed, and the contents are encrypted and copied onto a recording medium using this identification information.

### Solution to Problem

In order to solve the above problems, the present invention is a drive device for reading encrypted contents from a recording medium and outputting the encrypted contents to a host device, the drive device comprising: a read unit operable, when the host device issues an acquisition request for generation information used to generate a decryption key for an encrypted content, to read both the generation information and a digital signature, which is created using the generation information and a signing key, from a control area in the recording medium, restricting the digital signature for use only within the drive device, the control area being specified to have control information used only within the drive device; a verification unit operable to verify authenticity of the generation information using the digital signature; and an output control unit operable to output the generation information to the host device only when the generation information is judged to be authentic.

### ADVANTAGEOUS EFFECTS OF INVENTION

With the above-described structure, even if playback is attempted of a recording medium on which an unauthorized individual has written identification information using an unauthorized device, the read device in the present invention detects the unauthorized action via signature verification performed in the drive device and does not output an unauthorized key to the host device. Therefore, it is possible to prevent playback of contents from an unauthorized copy of a recording medium.

Also, since keys are protected by a signature, even if an unauthorized individual manages to write the keys on a recording medium, as long as the individual does not have the correct key for generating a signature, it would be difficult to forge a signature. Accordingly, it is possible to make it difficult for an unauthorized individual to create a recording medium that bypasses verification.

Moreover, since signature information recorded on the recording medium is not output to an external device, it is possible to prevent an unauthorized copy whereby data recorded on the recording medium is copied in its entirety using the drive device.

### BRIEF DESCRIPTION OF THE DRAWINGS

FIG. 1 is a block diagram showing the structure of a copyright protection system in an embodiment of the present invention.

FIG. 2 is a block diagram showing the structure of a certificate authority terminal device in an embodiment of the present invention.

FIG. 3 shows an example of signature information in an embodiment of the present invention.

FIG. 4 shows an example of signature information in an embodiment of the present invention.

FIG. 5 is a block diagram showing the structure of a contents provider terminal device in an embodiment of the present invention.

FIG. 6 shows an example of media key information in an embodiment of the present invention.

FIG. 7 shows an example of title key information in an embodiment of the present invention.

FIG. 8 shows an example of key configuration information in an embodiment of the present invention.

FIG. 9 shows an example of encrypted title keys in an embodiment of the present invention.

FIG. 10 shows examples of archive data, sectorized archive data, and a digital signal in an embodiment of the present invention.

FIG. 11 is a flowchart showing an encoding process in an embodiment of the present invention.

FIG. 12 shows an example of additional information in an embodiment of the present invention.

FIG. 13 shows an example of a replacement digital signal in an embodiment of the present invention.

FIG. 14 is a block diagram showing the structure of a recording medium in an embodiment of the present invention.

FIG. 15 is a block diagram showing the structure of a playback device in an embodiment of the present invention.

FIG. 16 is a block diagram showing the structure of a key issuing authority terminal device in an embodiment of the present invention.

FIG. 17 is a flowchart showing processing by a contents provider terminal device in an embodiment of the present invention.

FIG. 18 is a flowchart showing processing by a contents provider terminal device in an embodiment of the present invention.

FIG. 19 is a flowchart showing processing by a contents provider terminal device in an embodiment of the present invention.

FIG. 20 is a flowchart showing processing by a contents provider terminal device in an embodiment of the present invention.

FIG. 21 is a flowchart showing processing by a playback device in an embodiment of the present invention.

FIG. 22 is a block diagram showing the structure of a contents provider terminal device in an embodiment of the present invention.

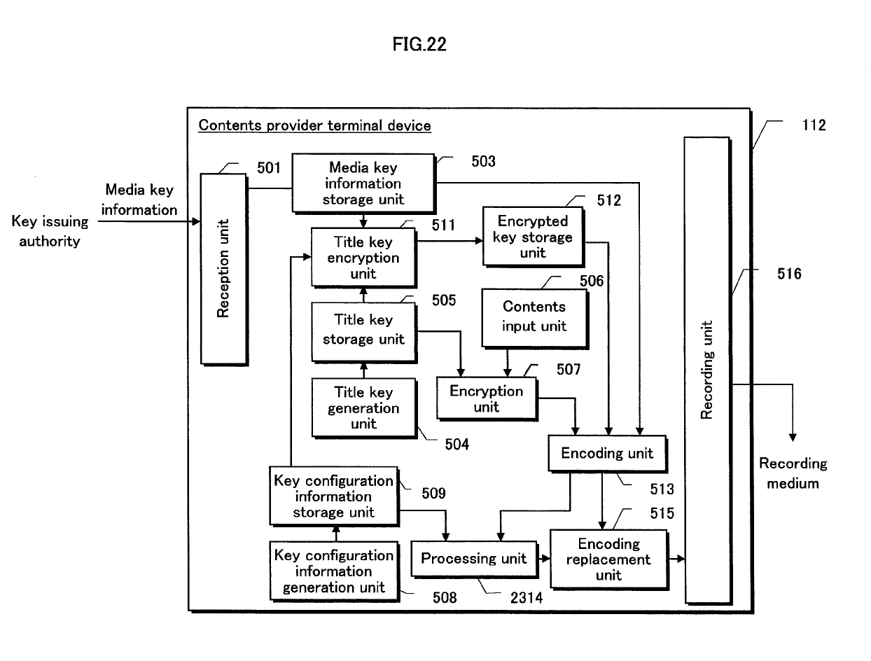

FIG. 23 shows an example of additional information in an embodiment of the present invention.

FIG. 24 shows the structure of a recording medium in an embodiment of the present invention.

FIG. 25 shows the structure of a recording medium in an embodiment of the present invention.

FIG. 26 is a block diagram showing the structure of a playback device in an embodiment of the present invention.

FIG. 27 is a flowchart showing processing by a contents provider terminal device in an embodiment of the present invention.

FIG. 28 shows whether or not playback is possible for combinations of a playback device and a recording medium in an embodiment of the present invention.

FIG. 29 is a block diagram showing the structure of a contents provider terminal device in an embodiment of the present invention.

FIG. 30 is a block diagram showing the structure of a contents provider terminal device in an embodiment of the present invention.

FIG. 31 shows an example of key configuration information in an embodiment of the present invention.

FIG. 32 shows an example of a component key recording status definition in an embodiment of the present invention.

FIG. 33 shows the structure of a recording medium in an embodiment of the present invention.

FIG. 34 is a block diagram showing the structure of a playback device in an embodiment of the present invention.

FIG. 35 shows an example of additional information in an embodiment of the present invention.

FIG. 36 shows the contents of a recording medium in an embodiment of the present invention.

FIG. 37 shows the contents of a recording medium in an embodiment of the present invention.

FIG. 38 illustrates the mutual relationship between keys in an embodiment of the present invention.

### DESCRIPTION OF EMBODIMENTS

In claim 1, one embodiment of the present invention, a drive device for reading encrypted contents from a recording medium and outputting the encrypted contents to a host device comprises: a read unit operable, when the host device issues an acquisition request for generation information used to generate a decryption key for an encrypted content, to read both the generation information and a digital signature, which is created using the generation information and a signing key, from a control area in the recording medium, restricting the digital signature for use only within the drive device, the control area being specified to have control information used only within the drive device; a verification unit operable to verify authenticity of the generation information using the digital signature; and an output control unit operable to output the generation information to the host device only when the generation information is judged to be authentic.

The control area may be specified to have an error correction code for data in a data recording area in the recording medium therein, the generation information and the digital signature may be recorded in a specific area in the control area, and the read unit may read the generation information and the digital signature from the specific area.

With the above-described structure, when attempting playback of a recording medium on which an unauthorized individual wrote identification information using an unauthorized device, the unauthorized action is detected via signature verification in the drive device, and unauthorized keys are not output to the host device. Therefore, it is possible to prevent playback of contents from an unauthorized copy of a recording medium.

Also, since keys are protected by a signature, even if an unauthorized individual manages to write the keys on a recording medium, as long as the individual does not have the correct key for generating a signature, it would be difficult to forge a signature. Accordingly, it is possible to make it difficult for an unauthorized individual to create a recording medium that bypasses verification.

Moreover, since signature information recorded on the recording medium is not output to an external device, it is possible to prevent an unauthorized copy whereby data recorded on the recording medium is copied in its entirety using the drive device.

Invalid data may be written in an area located within the data recording area and corresponding to the specific area, and the read unit (i) may not read the invalid data, (ii) may perform error correction when reading data recorded in the data recording area other than the invalid data, and (iii) may not perform error correction when reading the generation information and the digital signature.

With the above-described structure, it is possible to prevent detection of unnecessary errors via needless error correction processing.

The verification unit and the output control unit may be implemented only by hardware.

With the above-described structure, it becomes difficult to alter the verification unit and the output control unit. Accordingly, it is possible to make it difficult to perform unauthorized actions that avoid verification or output by altering these units.

The condition identification information that identifies a first writing condition and a second writing condition may be recorded on the recording medium, the first writing condition indicating that the generation information is positioned before the digital signature in the control area, and the second writing condition indicating that the digital signature is positioned before the generation information, and the read unit may read the condition identification information before reading the generation information and the digital signature, subsequently reading the generation information and the digital signature in accordance with the condition identification information.

With the above-described structure, the generation information and the digital signature can be read without mistake, regardless of whether the generation information is recorded before the digital signature on the recording medium or vice-versa. Accordingly, the present invention can coexist on the market with a drive device that can only read the generation information and digital signature when these are recorded in a specific order on the recording medium.

Condition identification information that identifies a first writing condition and a second writing condition may be recorded on the recording medium, the first writing condition indicating that the generation information and the digital signature are written in the control area, and the second writing condition indicating that the generation information and the digital signature are written with analog technology instead of being written in the control area, and the read unit may read the condition identification information before reading the generation information and the digital signature, subsequently reading the generation information and the digital signature in accordance with the condition identification information.

With the above-described structure, the generation information and the digital signature can be read from the recording medium, regardless of whether the generation information and the digital signature are written in a control area or written with analog technology, of which a ROM Mark is an example. Accordingly, the present invention can coexist on the market with a drive device that can only read the generation information and digital signature when these are written in a control area on the recording medium.

In claim 7, one embodiment of the present invention, a contents playback device for reading encrypted contents from a recording medium and playing back the encrypted contents comprises: a drive unit operable to read information from the recording medium; and a host unit operable to decrypt and play back an encrypted content using information acquired from the drive unit, the drive unit comprising: a read subunit operable, when the host unit issues an acquisition request for generation information used to generate a decryption key for the encrypted content, to read both the generation information and a digital signature, which is created using the generation information and a signing key, from a control area in the recording medium and to restrict the digital signature for use only within the drive unit, the control area being specified to have control information used only within the drive unit; a verification subunit operable to verify authenticity of the generation information using the digital signature; and an output control subunit operable to output the generation information to the host unit only when the generation information is judged to be authentic, the host unit comprising: a request subunit operable to issue the acquisition request to the read unit; a key generation subunit operable, upon acquiring the generation information from the drive unit, to generate the decryption key using the generation information; and a playback subunit operable to decrypt the encrypted content using the decryption key and play back the content.

When attempting playback of a recording medium on which an unauthorized individual wrote identification information using an unauthorized device, the unauthorized action is detected via signature verification in the drive device, and unauthorized keys are not output to the host device. Therefore, it is possible to prevent playback of contents from an unauthorized copy of a recording medium.

Also, since keys are protected by a signature, even if an unauthorized individual manages to write the keys on a recording medium, as long as the individual does not have the correct key for generating a signature, it would be difficult to forge a signature. Accordingly, it is possible to make it difficult for an unauthorized individual to create a recording medium that bypasses verification.

At least the verification unit and the output control unit within the drive unit may be implemented only by hardware.

With the above-described structure, it becomes difficult to alter the verification unit and the output control unit. Accordingly, it is possible to make it difficult to perform unauthorized actions that avoid verification or output by altering these units.

In claim 9, one embodiment of the present invention, a recording medium on which encrypted contents are recorded is a recording medium wherein generation information, used to generate a decryption key for an encrypted content, and a digital signature generated from the generation information are recorded in a control area, and condition identification information that identifies a first writing condition and a second writing condition is recorded at a specific position in a control area, the control area being specified to have control information used only within a drive device that reads data from the recording medium, the first writing condition indicating that the generation information is positioned before the digital signature, and the second writing condition indicating that the digital signature is positioned before the generation information.

With the above-described structure, the generation information and the digital signature can be read without mistake, regardless of whether the generation information is recorded before the digital signature on the recording medium or vice-versa. Accordingly, the present invention can coexist on the market with a drive device that can only read the generation information and digital signature when these are recorded in a specific order on the recording medium.

In claim 10, one embodiment of the present invention, a recording device for recording encrypted contents on a recording medium comprises: an acquisition unit operable to acquire generation information, used to generate a decryption key for an encrypted content, and a digital signature generated from the generation information; and a recording unit operable to record the generation information and the digital signature in a specific area on the recording medium, which has a data recording area and a control area in which an error correcting code for the data recorded on the data recording area is recorded, the specific area being within the control area, wherein invalid data is written in an area located within the data recording area and corresponding to the specific area.

The acquisition unit may include: a registration subunit operable to register input of the generation information used to generate a decryption key for the encrypted content; a transmission subunit operable to transmit the generation information to a certificate authority device; and a reception subunit operable to receive the digital signature generated by the certificate authority device for the generation information.

With the above-described structure, it is possible to generate a recording medium that is less likely than a conventional recording medium to be copied in an unauthorized manner.

When attempting playback of a recording medium on which an unauthorized individual wrote identification information using an unauthorized device, the unauthorized action is detected via signature verification in the drive device, and unauthorized keys are not output to the host device. Therefore, it is possible to prevent playback of contents from an unauthorized copy of a recording medium.

Also, since keys are protected by a signature, even if an unauthorized individual manages to write the keys on a recording medium, as long as the individual does not have the correct key for generating a signature, it would be difficult to forge a signature. Accordingly, it is possible to make it difficult for an unauthorized individual to create a recording medium that bypasses verification.

In claim 12, one embodiment of the present invention, a data reading method, used in a drive device for reading encrypted contents from a recording medium and outputting the encrypted contents to a host device, comprises the steps of: reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device; verifying authenticity of the generation information using the digital signature; and outputting the generation information to the host device only when the generation information is judged to be authentic.

In claim 13, one embodiment of the present invention, a data reading program, used in a drive device for reading encrypted contents from a recording medium and outputting the encrypted contents to a host device, comprises the steps of: reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device; verifying authenticity of the generation information using the digital signature; and outputting the generation information to the host device only when the generation information is judged to be authentic.

In claim 14, one embodiment of the present invention, a computer readable recording medium stores a data reading program, used in a drive device for reading encrypted contents from a recording medium and outputting the encrypted contents to a host device, the data reading program comprising the steps of: reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device; verifying authenticity of the generation information using the digital signature; and outputting the generation information to the host device only when the generation information is judged to be authentic.

In claim 15, one embodiment of the present invention, an integrated circuit, used in a drive device for reading encrypted contents from a recording medium and outputting the encrypted contents to a host device, comprises the steps of: reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device; verifying authenticity of the generation information using the digital signature; and outputting the generation information to the host device only when the generation information is judged to be authentic.

With the above-described structure, when attempting playback of a recording medium on which an unauthorized individual wrote identification information using an unauthorized device, the unauthorized action is detected via signature verification in the drive device, and unauthorized keys are not output to the host device. Therefore, it is possible to prevent playback of contents from an unauthorized copy of a recording medium.

Also, since keys are protected by a signature, even if an unauthorized individual manages to write the keys on a recording medium, as long as the individual does not have the correct key for generating a signature, it would be difficult to forge a signature. Accordingly, it is possible to make it difficult for an unauthorized individual to create a recording medium that bypasses verification.

Moreover, since signature information recorded on the recording medium is not output to an external device, it is possible to prevent an unauthorized copy whereby data recorded on the recording medium is copied in its entirety using the drive device.

Embodiments of the present invention are described below with reference to the drawings.

### 1. Embodiment 1

The copyright protection system in an embodiment of the present invention is for preventing unauthorized copies of a recording medium on which encrypted contents are recorded. Unauthorized copying is assumed not to be a large-scale attack wherein exact copies are created using equipment to manufacture recording media, but rather an attack that combines a host device (Personal Computer (PC) or the like) and a commercial drive to read data from a recording medium, such as a DVD. By analyzing the operation of player software operating on the host device, an unauthorized individual exposes identification information (VolumeID) that is unique to a recording medium and is used to generate a decryption key for encrypted contents recorded on the recording medium. The unauthorized individual then uses this identification information and his or her own encoder to re-encrypt the contents whose encryption was cracked and copy the contents onto an unused (fresh) recording medium. A recording medium copied in this way can be played back by another commercial player.

1.1 Structure

1.1.1 Outline of Overall Structure of Copyright Protection System

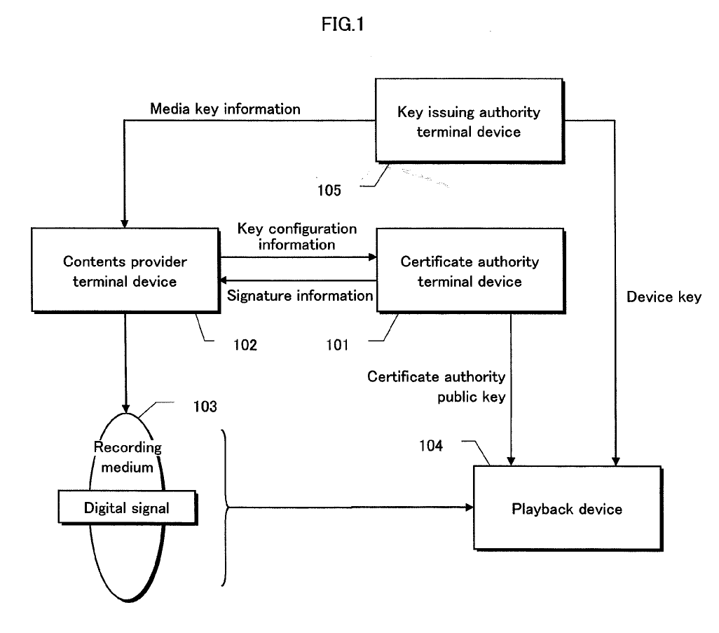

As shown in FIG. 1, the copyright protection system in an embodiment of the present invention includes: a contents provider terminal device 102 that provides a recording medium 103 by generating, encrypting, and then writing contents on the recording medium 103 as a digital signal; a playback device 104 that decrypts contents from the digital signal written on the recording medium 103; a key issuing authority terminal device 105 that issues keys for encrypting and decrypting contents; and a certificate authority terminal device 101 that generates a signature to certify the authenticity of a key.

Contents that are the target of copyright protection are encrypted using a title key and then stored on the recording medium 103 as a digital signal. These contents can then only be played back by a playback device that can generate an authentic title key.

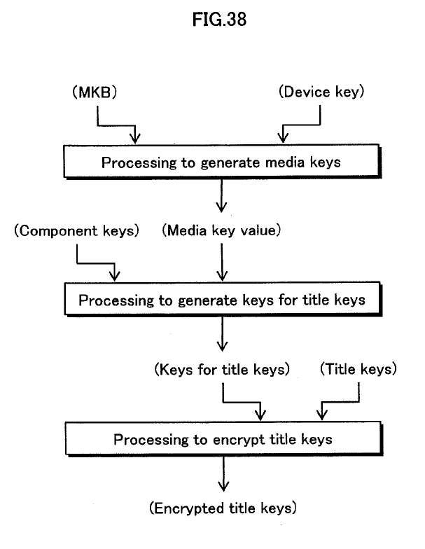

FIG. 38 is a schematic diagram showing the mutual relationship between keys used in the present embodiment.

The title key used for encryption of contents is encrypted with a key for the title key and then stored on the recording medium 103 as encrypted title key information. The key for the title key is generated from a component key and the value of a media key. The component key is information unique to the medium, and for example corresponds to the VolumeID on a Blu-ray Disc (BD) or the like. The component key is stored on the recording medium 103 as part of the additional information that accompanies the contents. The value of the media key is the value of the key generated from the Media Key Block (MKB) recorded on the recording medium 103 and the device key stored by the playback device.

The device key information, which includes the device key and the media keys, is generated by the key issuing authority terminal device 105. The device key is different for each device. The key issuing authority terminal device 105 provides the playback device 104 with the device key and provides the contents provider terminal device 102 with the media key information. The contents provider terminal device 102 creates and stores, in advance, contents and a title key to provide to users. The contents provider terminal device 102 uses the title key to perform encryption and other processing on the contents and store the contents on the recording medium 103. Furthermore, the contents provider terminal device 102 sends key configuration information, which is information that includes the component key, to the certificate authority terminal device 101 and receives, as a response from the certificate authority terminal device 101, signature information for the key configuration information that was sent.

The contents provider terminal device 102 records additional information, which is processed key configuration information and signature information, encrypted contents, etc. on the recording medium 103. While processing is described below, an example is processing to concatenate key configuration information and signature information.

The certificate authority terminal device 101 generates and stores a certificate authority private key and a certificate authority public key. After the certificate authority terminal device 101 receives key configuration information from the contents provider terminal device 102, it generates signature information for the key configuration information using the certificate authority private key and sends the signature information to the contents provider terminal device 102.

The playback device 104 stores, in advance, the certificate authority private key generated by the certificate authority terminal device 101. The playback device 104 reads the signature information included in the additional information stored on the recording medium 103 and verifies the authenticity of the signature information using the certificate authority public key. If the signature information is not authentic, the playback device 104 does not perform playback processing on the contents. If the signature information is authentic, the playback device 104 restores the title key using the device key, the media key information recorded on the recording media 103, etc. and then decrypts and plays back the encrypted contents.

This signature information is used after being read from a recording medium 103 by a drive, implemented only by hardware, in the playback device 104. This signature information is not output to a device external to the drive. Accordingly, the signature information cannot be ascertained even by analyzing the operation of player software operating on a host device (playback device), as described above. Accordingly, the signature information cannot be acquired, except in special cases such as an unauthorized hardware analysis of the drive itself. Accordingly, the contents of the recording medium 103, including the signature information, cannot be copied. Moreover, it is the certificate authority terminal device 101 that generates the signature information, and unauthorized individuals cannot generate, on their own, signature information that would be judged authentic during signature verification by a normal drive device. In this way, by using signature information, it is possible to prevent unauthorized copying of a recording medium.

1.1.2 Structure of the Certificate Authority Terminal Device 101

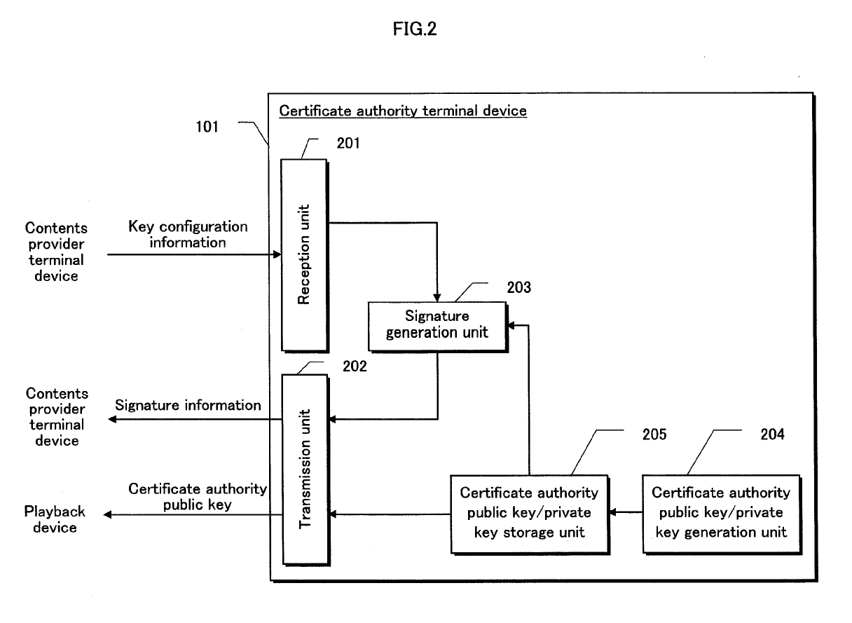

As shown in FIG. 2, the certificate authority terminal device 101 includes a reception unit 201, transmission unit 202, signature generation unit 203, certificate authority public key/private key generation unit 204, and a certificate authority public key/private key storage unit 205.

Specifically, the certificate authority terminal device 101 includes a microprocessor, Random Access Memory (RAM), Read Only Memory (ROM), hard disk, etc. which are not shown in the figures. Computer programs are stored on the RAM, ROM, and hard disk. The microprocessor operates in accordance with the computer programs, and the certificate authority terminal device 101 thereby fulfills its functions.

The reception unit 201 receives data from other devices. As an example, the reception unit receives, from the contents provider terminal device 102, key configuration information generated by the contents provider terminal device 102.

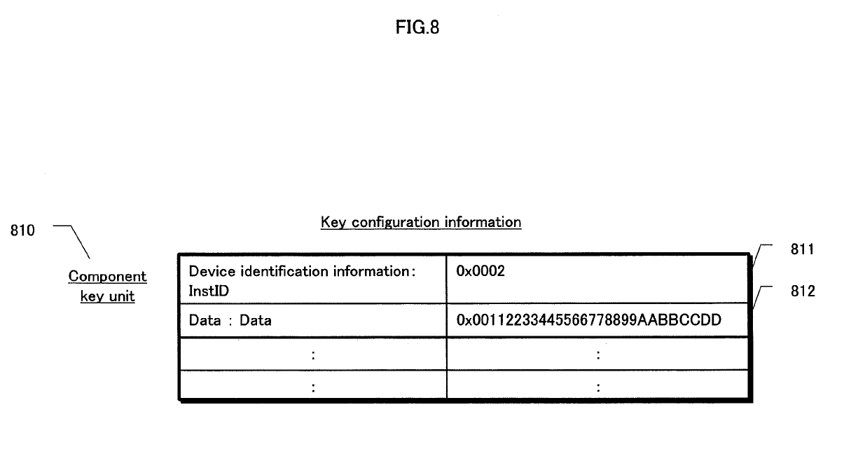

FIG. 8 shows an example of key configuration information.

The key configuration information includes a component key unit 810. A fixed value (hereinafter, “InstID”), assigned to each key configuration information embedding system, is written in a device identification information field 811 in the component key unit 810. Different values for the InstID are allocated, for example, to different manufacturers of key configuration information embedding systems. The component key is recorded in a data field 812.

The certificate authority public key/private key generation unit 204 generates a pair of a public key used by the certificate authority (hereinafter, “certificate authority public key”) and a corresponding private key (hereinafter, “certificate authority private key”) and stores the generated pair in the certificate authority public key/private key storage unit 205. Also, the certificate authority public key/private key generation unit 204 uses the transmission unit 202 to send the certificate authority public key to the playback device 104.

Upon receiving data targeted for signature generation and a signature generation request, the signature generation unit 203 generates a signature for the received data using the certificate authority private key and uses the transmission unit 202 to send the signature to the contents provider terminal device 102. Specifically, the signature generation unit 203 calculates a hash value for the entire key configuration information received via the reception unit 201 and generates a signature for the hash value. In the present embodiment, a signature refers to a standard digital signature. Technology for assigning a digital signature is widely known, and therefore an explanation thereof is omitted.

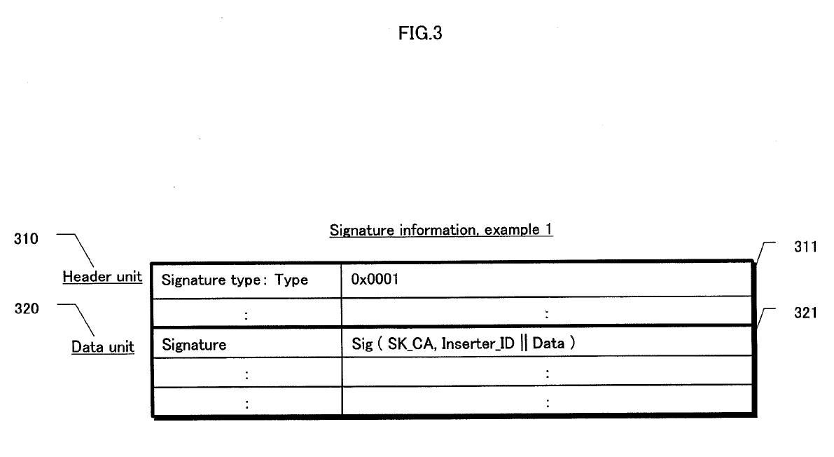

FIG. 3 shows an example of signature information generated by the signature generation unit 203.

Signature information is composed of a header unit 310 and a data unit 320. A signature type field 311, which is an area for recording the signature type, is provided in the header unit 310. A signature field 321 is provided in the header unit 320. The signature generated by the signature generation unit 203 is written in the signature field 321.

The transmission unit 202 transmits data to other devices.

1.1.3 Structure of the Contents Provider Terminal Device 102

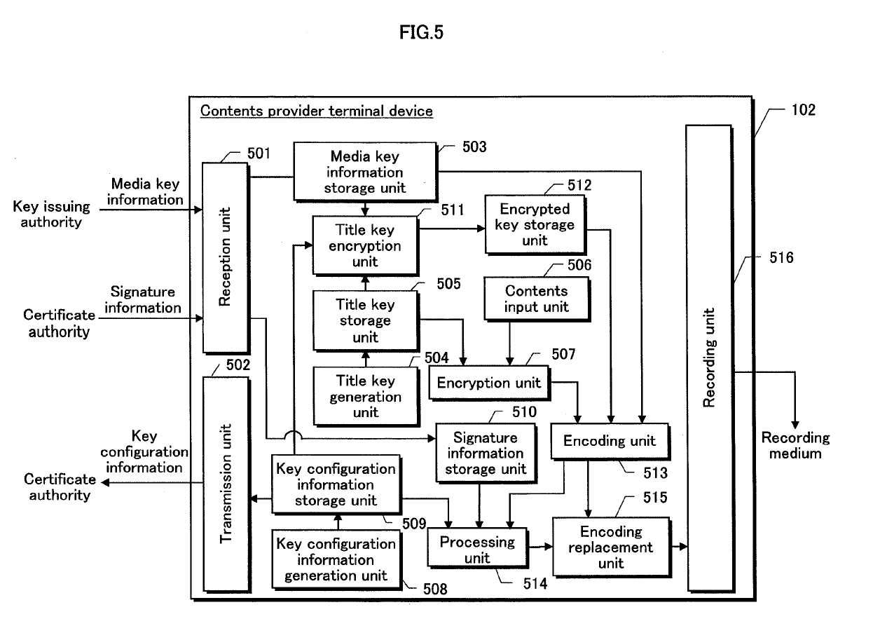

As shown in FIG. 5, the contents provider terminal device 102 includes a reception unit 501, a transmission unit 502, media key information storage unit 503, title key generation unit 504, title key storage unit 505, contents input unit 506, encryption unit 507, key configuration information generation unit 508, key configuration information storage unit 509, signature information storage unit 510, title key encryption unit 511, encrypted key storage unit 512, encoding unit 513, processing unit 514, encoding replacement unit 515, and recording unit 516.

Specifically, the contents provider terminal device 102 includes a microprocessor, RAM, ROM, hard disk, etc. which are not shown in the figures. Computer programs are stored on the RAM, ROM, and hard disk. The microprocessor operates in accordance with the computer programs, and the certificate authority terminal device 102 thereby fulfills its functions.

The reception unit 501 receives media key information from the key issuing authority terminal device 105 and stores the media key information in the media key information storage unit 503.

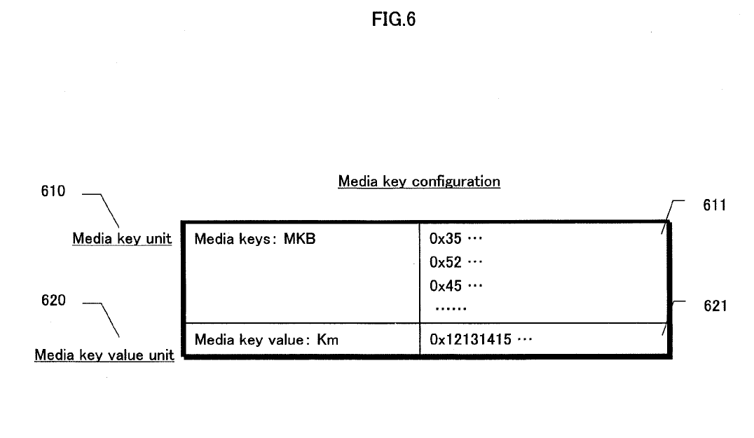

FIG. 6 shows an example of media key information.

Media key information is composed of a media key unit 610, on which media keys are written, and a media key value unit 620, on which a media key value is written. This media key value can be acquired as described above by processing the media keys and the device key, and thus it is not absolutely necessary to include the media key value in the media key information. The present redundant structure has been adopted on purpose under the assumption that the contents provider terminal device may not have the device key.

The reception unit 501 receives signature information from the certificate authority terminal device 101.

The title key generation unit 504 generates title keys for encrypting the contents and generates title key information.

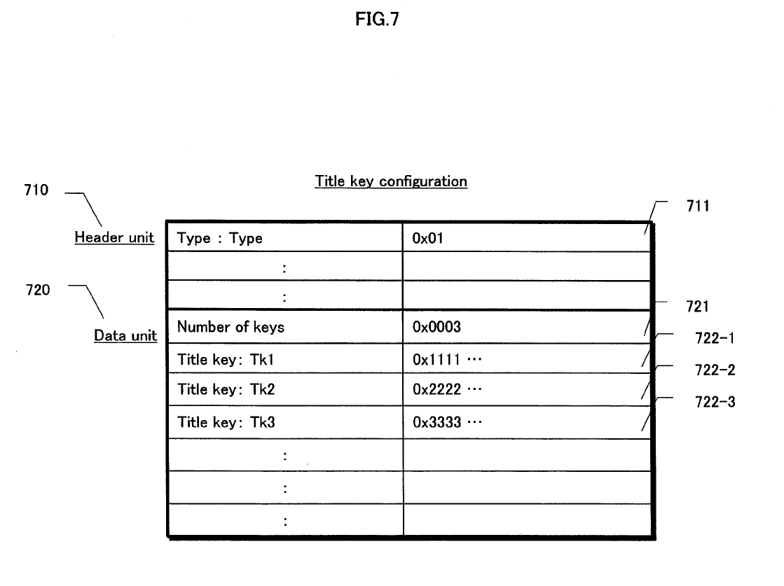

FIG. 7 shows an example of title key information.

Title key information is composed of a header unit 710 and a data unit 720. A type field 711 in the header unit 710 indicates format identification information for the title key information. A key number field 721 in the data unit 720 indicates the number of title keys included in the title key information. For example, in the case of FIG. 7, this means that the title key information contains three title keys. The generated title keys are written in the title key fields 722-1 through 722-3 in the data unit 720.

The title key storage unit 505 stores title key information generated by the title key generation unit 504.

The contents input unit 506 receives the input contents.

The encryption unit 507 uses the title keys included in the title key information stored by the title key storage unit 505 to encrypt the contents input into the contents input unit 506, thereby generating encrypted contents.

The key configuration information generation unit 508 generates key configuration information including component keys used in calculation of the keys for the title keys, which encrypts the title keys.

The key configuration information storage unit 509 stores the key configuration information generated by the key configuration information generation unit 508.

The signature information storage unit 510 stores signature information received by the reception unit 501.

The title key encryption unit 511 receives the key configuration information stored by the key configuration information storage unit 509 and extracts the component keys from within the key configuration information. The title key encryption unit 511 also receives the media key information stored by the media key information storage unit 503 and extracts the media key value from within the media key information. Then, the title key encryption unit 511 generates keys for the title keys, which encrypt the title keys, from the extracted component keys and media key value. Using the key for the title key, the title key encryption unit 511 encrypts the title keys in the title key information stored by the title key storage unit 505, overwriting the encrypted title keys in the title key fields 722-1 through 722-3 in FIG. 7 to generate encrypted title key information.

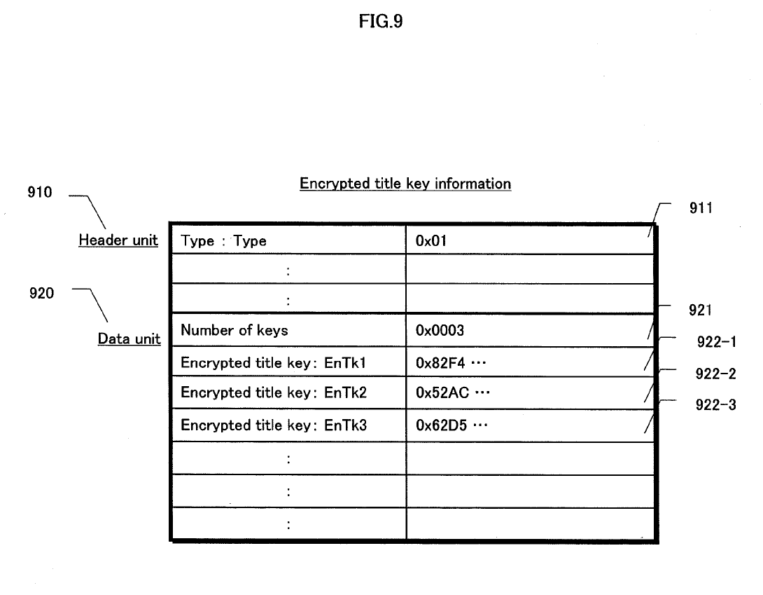

FIG. 9 shows an example of encrypted title keys.

Encrypted title key information is composed of a header unit 910 and a data unit 920. Identification information identifying the format of the title key information is recorded in a type field 911 in the header unit 910. A key number field 921 in the data unit 920 indicates the number of title keys defined by the encrypted title key information. For example, in the case of FIG. 9, this means that there are three encrypted title keys.

The encrypted title keys, which are title keys that have been encrypted, are written in the encrypted title key fields 922-1 through 922-3 in the data unit 920. In the example in FIG. 9, the title key encryption unit 511 generates three encrypted title keys and writes them respectively in the encrypted title key fields 922-1, 922-2, and 922-3 in the data unit 920 in the encrypted title key information.

The encrypted key storage unit 512 stores the encrypted title key information generated by the title key encryption unit 511.

The encoding unit 513 receives data, such as: the encrypted contents, which are encrypted by the encryption unit 507; the encrypted title key information, which is stored by the encrypted key storage unit 512; and the media key extracted from the media key information stored by the media key information storage unit 503. The encoding unit 513 then combines this data and generates archive data.

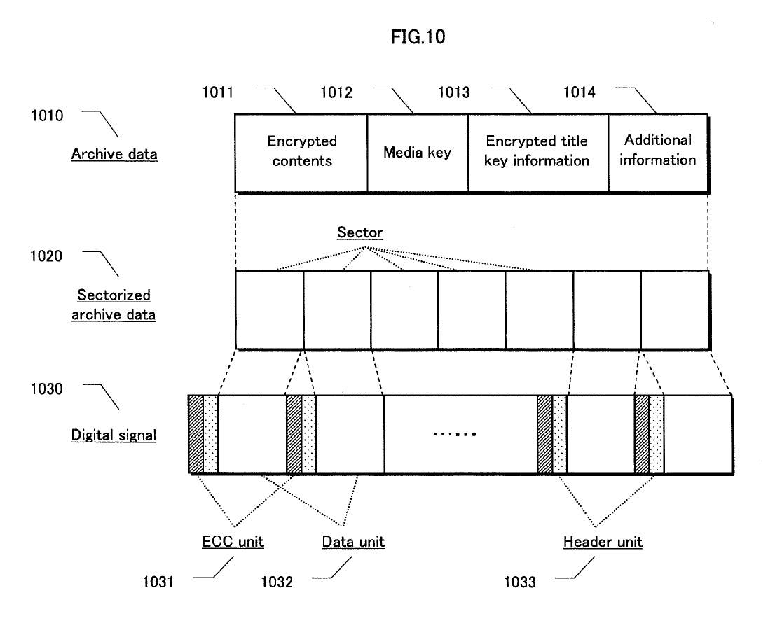

FIG. 10 shows an example of archive data. Archive data 1010 is data in which encrypted contents 1011, a media key 1012, encrypted title key information 1013, and additional information 1014 are concatenated and continuously arranged. Next, the encoding unit 513 encodes the archive data 1010.

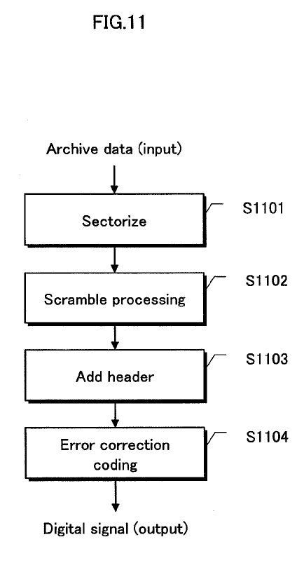

FIG. 11 is a flowchart showing the process by which the encoding unit 513 encodes the archive data 1010.

The encoding unit 513 divides the archive data 1010 into sectors in units of a predetermined data amount, e.g. units of 2048 bytes (step S1101). Next, the sectorized archive data 1020, obtained by division into sectors, is scrambled using sector addresses corresponding to the sectors (step S1102). Then, header data containing information such as sector addresses is provided as the header unit 1033 at the top of each sector (step S1103). Furthermore, data delay and parity calculation are performed on the sectorized data, and a digital signal 1030 with an error correcting code (ECC) added to the ECC unit 1031 is generated (step S1104). The generated digital signal 1030 includes an ECC unit 1031, a data unit 1032, and a header unit 1033.

The processing unit 514 concatenates the key configuration information and signature information to generate additional information.

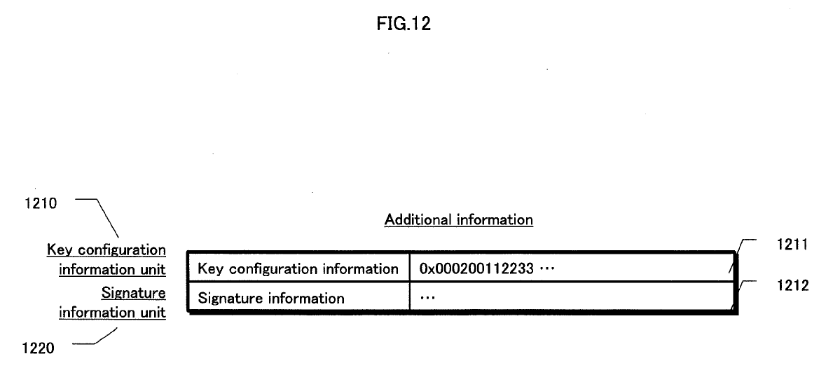

FIG. 12 shows an example of additional information.

Additional information includes a key configuration information unit 1210, in which the key configuration information is written, and a signature information unit 1220, in which signature information is written.

In this embodiment, the media key 1012, encrypted title key information 1013, and additional information 1014 are included in the archive data 1010, but these pieces of information can be generated from other pieces of information and thus do not need to be included in the archive data 1010. The present redundant structure has been adopted on purpose under the assumption that the contents provider terminal device may not have the relevant pieces of information.

The encoding replacement unit 515 replaces a section in the ECC unit 1031 in the digital signal output by the encoding unit 513 with additional information generated by the processing unit 514 and outputs a replacement digital signal. At this point, the recording position in the ECC unit 1031 at which data is replaced by additional information is written in embedded location information. This embedded location information is recorded at a particular address in the recording medium. Accordingly, when a playback device or the like is to read the additional information, it first refers to the embedded location information recorded at a particular address in the recording medium (e.g. a predetermined address, such as storage location 10000) and then reads the additional information recorded at the recording location written in the embedded location information.

In this embodiment, when an ECC is replaced by additional information, error correction for the data targeted for error correction by this ECC becomes impossible. The additional information, however, is recorded in an ECC unit for a data recording area in which invalid data is recorded and which does not require error correction; hence there is no problem.

Note that since the data recorded in the ECC unit is used for error correction, it is used inside a drive device that reads a recording medium, and the data is not output to a device external to the drive device.

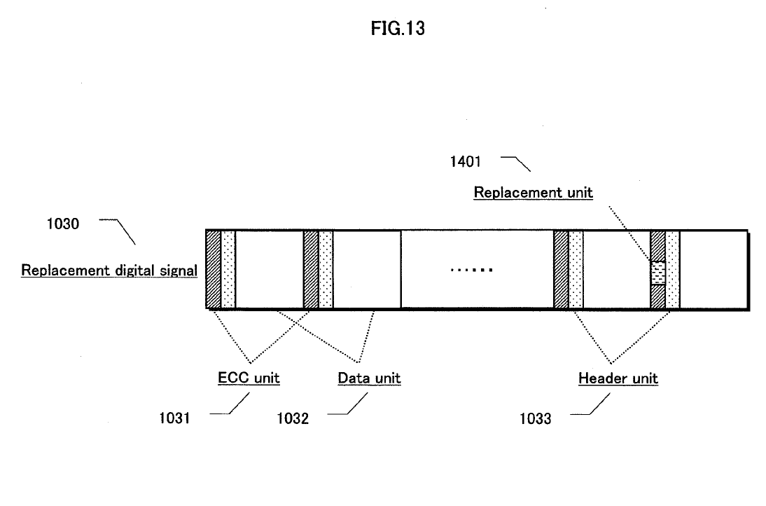

FIG. 13 shows an example of a replacement digital signal.

In the replacement digital signal 1030, a replacement unit 1401, which is part of the ECC unit 1031, has been replaced with additional information.

The recording unit 516 receives the replacement digital signal from the encoding replacement unit 515 and records it on the recording medium 103.

The transmission unit 502 transmits the key configuration information to the certificate authority terminal device 101.

1.1.4 Structure of the Recording Medium 103

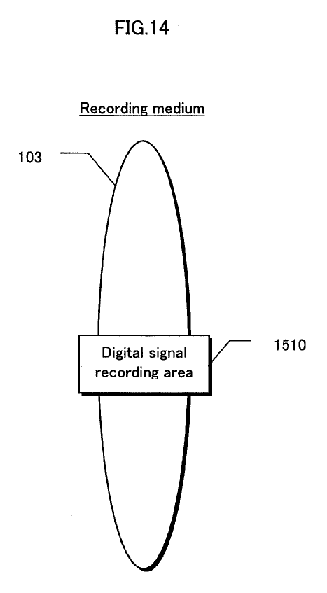

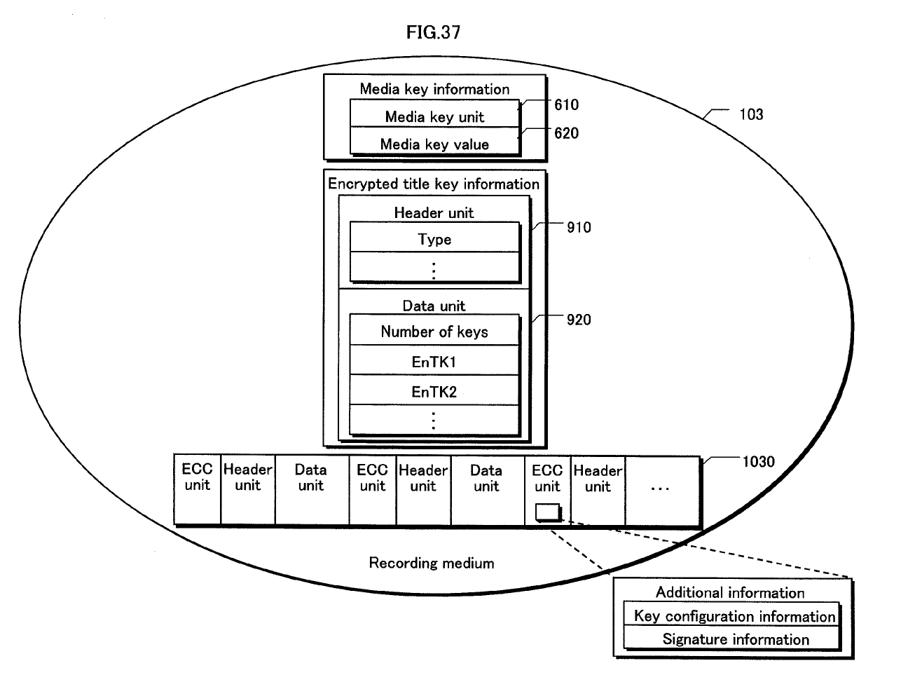

As shown in FIG. 14, the recording medium 103 has a digital signal recording area 1510 in which a digital signal is recorded. As shown in FIG. 37, media key information, encrypted title key information, and a replacement digital signal are recorded on the recording medium 103.

1.1.5 Structure of the Playback Device 104

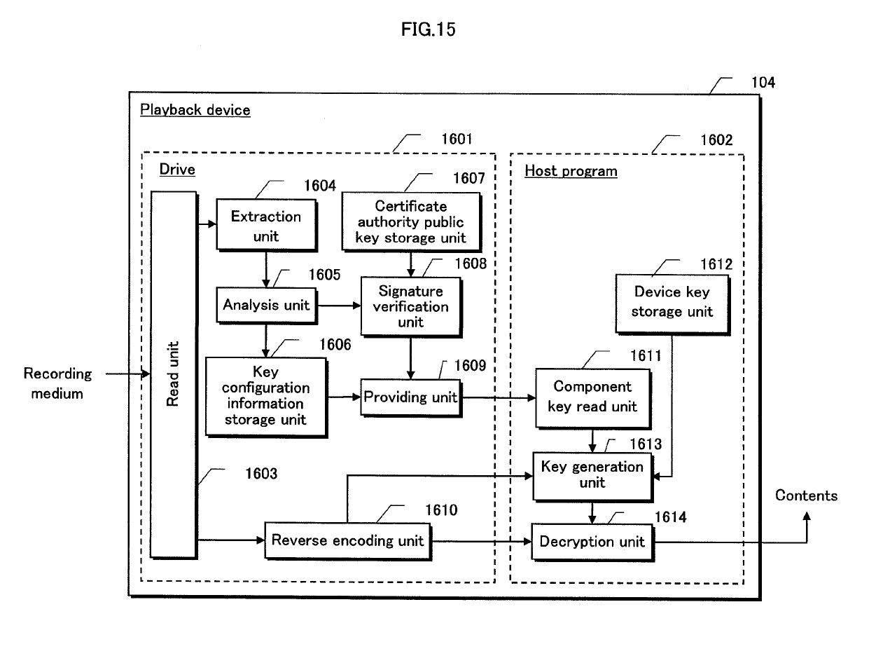

As shown in FIG. 15, the playback device 104 consists of a drive 1601 and a host program 1602. Specifically, the playback device 104 consists of a microprocessor, RAM, ROM, hard disk, etc. which are not shown in the figures. In this embodiment, a host program 16 indicates not only the program itself, but also includes various means to execute a program such as a microprocessor, RAM, ROM, a variety of Large Scale Integrations (LSI), etc. and other hardware.

The drive 1601 is a read device that reads an error correction code from the recording medium 103 and also reads a digital signal therefrom while performing error correction processing. The drive 1601 is composed of a read unit 1603, extraction unit 1604, analysis unit 1605, key configuration information storage unit 1606, certificate authority public key storage unit 1607, signature verification unit 1608, providing unit 1609, and reverse encoding unit 1610.

The read unit 1603 reads a digital signal from the recording medium 103.

The extraction unit 1604 analyzes the digital signal read by the read unit 1603 and, with reference to the embedded location information recorded at a particular address in the recording medium 103, extracts the additional information recorded in the position indicated by the embedded location information.

The analysis unit 1605 separates and outputs key configuration information and signature information from the additional information extracted by the extraction unit 1604.

The key configuration information storage unit 1606 stores the key configuration information output by the analysis unit 1605.

The certificate authority public key storage unit 1607 receives and stores a certificate authority public key from the certificate authority terminal device 101 at the time the playback device 104 is manufactured.

The signature verification unit 1608 receives the key configuration information and signature information output by the analysis unit 1605. The signature verification unit 1608 also uses the certificate authority public key stored in the certificate authority public key storage unit 1607 to perform signature verification on the key configuration information, outputting the signature verification results (success or failure) to the providing unit 1609.

The providing unit 1609 receives a request for the component keys from the component key read unit 1611 in the host program 1602, which is described below. At this point, the providing unit 1609 only provides the component key read unit 1611 with the component keys in the key configuration information stored by the key configuration information storage unit 1606 when the signature verification results output by the signature verification unit 1608 indicate success. When the signature verification results indicate failure, the component keys are not provided. In this way, when the component keys have been fraudulently manipulated, playback of the contents by the host program 1602 can be stopped. Note that unauthorized action to analyze the drive 1601 and forcefully acquire the component keys is conceivable; however, as described above, the drive 1601 is configured via a hardware implementation. Therefore, such analysis would not be easy, making such unauthorized action difficult.

The reverse encoding unit 1610 receives a digital signal read by the read unit 1603 and performs, on the received digital signal, procedures opposite to the encoding process carried out by the encoding unit 513 in the contents provider terminal device 102. These opposite procedures include error correction, header analysis, descramble processing, sector combination, and partitioning. In this way, the reverse encoding unit 1610 restores archived data such as the encrypted contents, media key, and encrypted title key information. By performing error correction at this point, the additional information replaced by the encoding replacement unit 515 is lost, and thus the output data does not include additional information.

The host program 1602 is composed of a component key read unit 1611, device key storage unit 1612, key generation unit 1613, and decryption unit 1614.

The component key read unit 1611 requests the component keys from the drive 1601, and receives the component keys as a response.

The device key storage unit 1612 stores the device key transmitted from the key issuing authority terminal device 105.

Note that the device key is written on the playback device 104 at the time of manufacture.

The key generation unit 1613 receives the encrypted title keys from the reverse encoding unit 1610, receives the component keys from the component key read unit 1611, and receives the device key from the device key storage unit 1612.

The key generation unit 1613 also processes the media keys and device key to calculate the media key value, and furthermore processes the component keys to calculate and output the keys for the title keys.

Furthermore, the key generation unit 1613 receives the encrypted title key information from the reverse encoding unit 1610, generates the title keys by decrypting the encrypted title keys in the encrypted title, key information using the keys for the title keys, and then outputs the title keys.

The decryption unit 1614 receives the encrypted contents output from the reverse encoding unit 1610, receives the title keys from the key generation unit 1613, decrypts the encrypted contents using the title keys, and outputs the contents.

1.1.6 Structure of the Key Issuing Authority Terminal Device 105

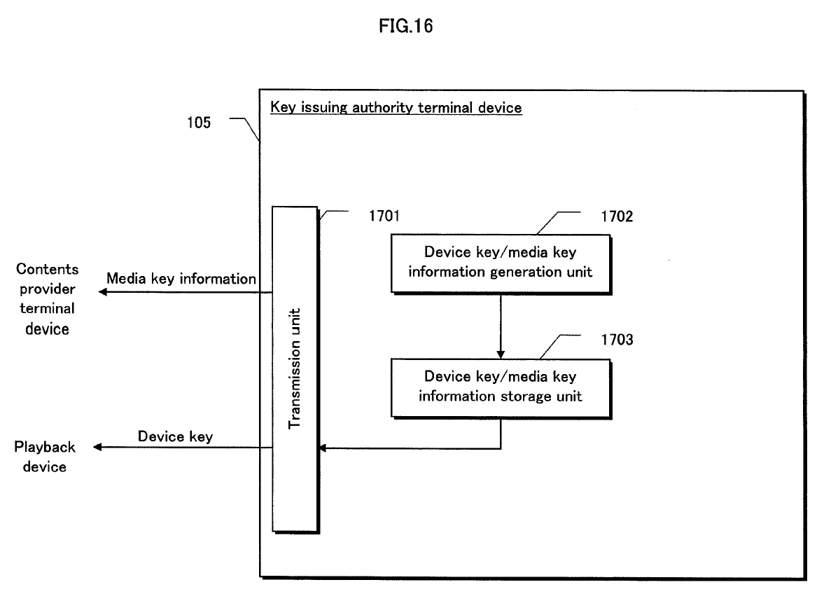

As shown in FIG. 16, the key issuing authority terminal device 105 consists of a transmission unit 1701, device key/media key information generation unit 1702, and device key/media key information storage unit 1703.

Specifically, the key issuing authority terminal device 105 includes a microprocessor, RAM, ROM, hard disk, etc. which are not shown in the figures. Computer programs are stored on the RAM, ROM, and hard disk. The microprocessor operates in accordance with the computer programs, and the key issuing authority terminal device 105 thereby fulfills its functions.

The device key/media key information generation unit 1702 generates a device key and media key information and stores them in the device key/media key information storage unit 1703.

The transmission unit 1701 transmits the media key information stored by the device key/media key information storage unit 1703 to the contents provider terminal device 102 as necessary. The transmission unit 1701 also transmits the media key information stored by the device key/media key information storage unit 1703 to the playback device 104 as necessary. As described above, the media key value is calculated by processing the media keys and the device key. The method to generate the media key value is widely known and is not included here, as it is not fundamental to the present invention.

1.2 Operation

1.2.1 Operations of the Contents Provider Terminal Device 102

Operations of the contents provider terminal device 102 are described with reference to the figures in the following processing order: processing to generate additional information, processing to generate encrypted title key information, processing to generate an encrypted title key, and processing from encoding through recording on the recording medium.

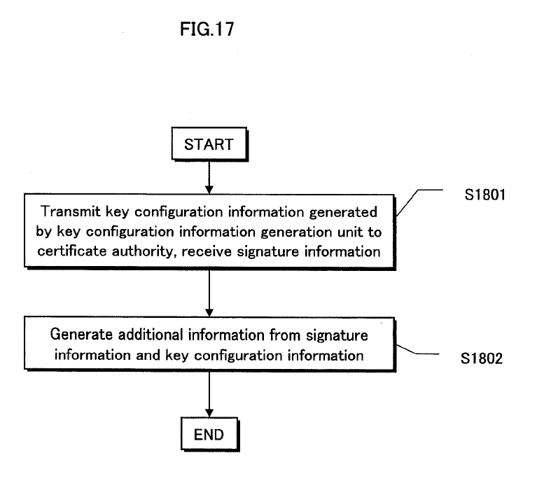

First, processing to generate additional information is explained with reference to FIG. 17.

The key configuration information generation unit 508 in the contents provider terminal device 102 generates key configuration information and stores it in the key configuration information storage unit 509. The transmission unit 502 transmits the key configuration information stored in the key configuration information storage unit 509 to the certificate authority terminal device 101. The reception unit 501 receives from the certificate authority terminal device 101, as a response to the transmission, a signature corresponding to the key configuration information (step S1801). The processing unit generates additional information from the signature information and the key configuration information (step S1802).

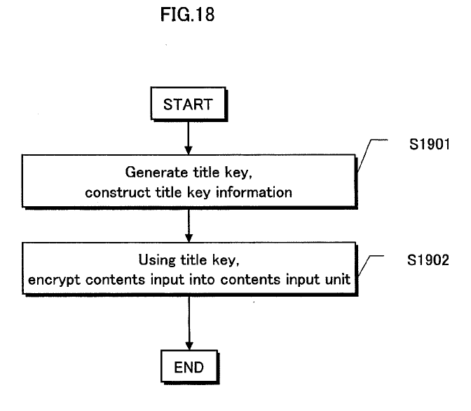

Next, processing to generate encrypted title key information is explained with reference to FIG. 18.

The title key generation unit 504 in the contents provider terminal device 102 generates a title key and stores it as title key information in the title key storage unit 505 (step S1901). Furthermore, the encryption unit 507 uses the title key to encrypt the contents input into the contents input unit 506 (step S1902).

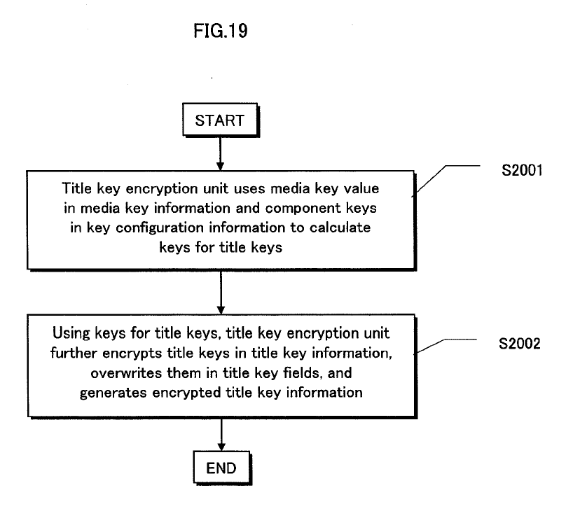

Processing to generate encrypted title keys is explained with reference to FIG. 19.

The title key encryption unit 511 in the contents provider terminal device 102 calculates a key for the title key using the media key value in the media key information and the component key in the key configuration information (step S2001). Then, using the key for the title key, the title key encryption unit 511 encrypts the title key in the title key information and overwrites it in the title key field to generate encrypted title key info/Ration (step S2002).

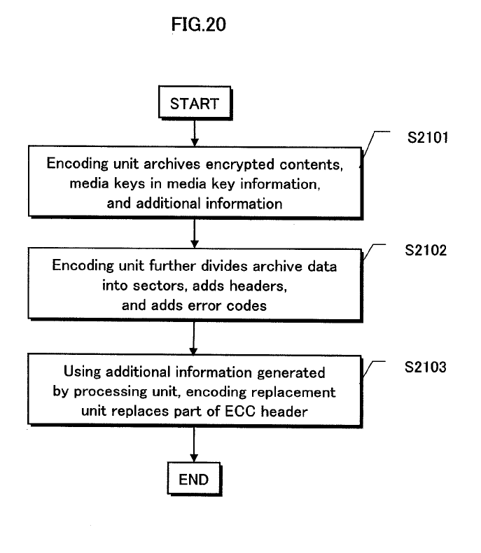

Next, processing from encoding through recording on the recording medium is explained with reference to FIG. 20.

The encoding unit in the contents provider terminal device 102 archives encrypted contents, the media key in the media key information, encrypted title key information, and additional information, thus generating archive data (step S2101). Furthermore, the encoding unit divides the archive data into sectors and adds headers (step S2102). Furthermore, the encoding replacement unit 515 replaces a section in the ECC unit in the digital signal with additional information.

1.2.2 Operations of the Playback Device 104

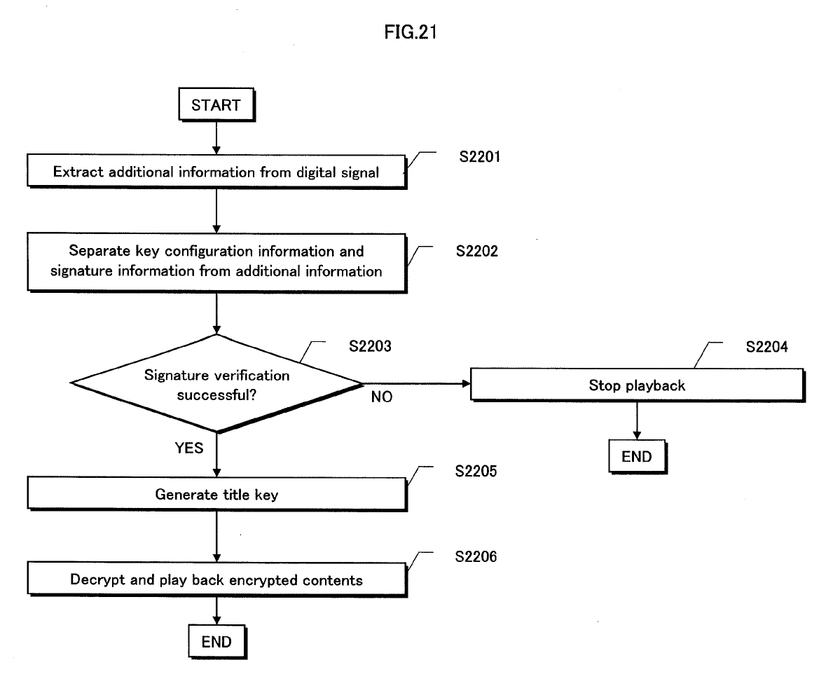

Operations of the playback device 104 are explained with reference to FIG. 21.

First, the read unit 1603 in the playback device 104 reads a digital signal. The extraction unit 1604 extracts additional information from the digital signal read by the read unit 1603 (step S2201). Next, the analysis unit 1605 separates the key configuration information and signature information from the additional information (step S2202). The signature verification unit 1608 receives the key configuration information and signature information from the analysis unit 1605 and performs signature verification on the key generation information using the signature included in the signature information (step S2203). When signature verification fails (step S2203: NO), playback is stopped (step S2204). Specifically, even if the drive 1601 receives a request for component key information, the providing unit 1609 in the drive 1601 does not return the component key to the host program 1602, responding for example with an error. Upon receiving an error response, the host program 1602 stops playback of the corresponding disc and notifies the user that playback is impossible, for example by only accepting a command to eject the disc, showing a window on the screen indicating that the disc is unauthorized, etc.

Conversely, when signature verification succeeds (step S2203: YES), the host program 1602 returns a component key via the providing unit 1609 in response to a request, issued by the component key read unit 1611 to the drive 1601, for the component key information.

The key generation unit 1613 calculates the media key value using the device key and the media key output by the reverse encoding unit 1610 and calculates the key for the title key using the media key value and the component keys. Furthermore, the key generation unit 1613 decrypts the encrypted title key in the encrypted title key information output by the reverse encoding unit 1610 using the key for the title key, thus calculating the title key (step S2205). Next, using the calculated title key, the key generation unit 1613 decrypts the encrypted contents output by the reverse encoding unit 1610, and performs playback processing to output and decode the contents (step S2206).

The operations of devices other than the playback device 104 and the contents provider terminal device 102 are obvious from the detailed description of these devices, and thus an explanation thereof is omitted.

### 2. Embodiment 2

With the playback device 104 in Embodiment 1, a problem occurs wherein an existing (or “legacy”) recording medium cannot be read. In the present embodiment, a contents provider terminal device that generates a recording medium while taking this problem into consideration is described.

Hereinafter in the present description, “legacy” refers to including only identification information in the ECC, without including an electronic signature. In other words, a legacy recording medium is a recording medium that does not have a digital signature recorded in the ECC, but rather only has identification information recorded in the ECC. Similarly, a legacy system refers to a system that uses a legacy recording medium. Furthermore, a system that inserts in the ECC additional information including a digital signature, as in the embodiment described above, is referred to hereinafter as a “new system.” The terms “legacy system,” “new system,” etc. are only used, however, for the sake of convenience in the present description; these terms do not have any special meaning, nor are they meant to be limiting in any way.

For the sake of contrast with the contents provider terminal device described in the present embodiment, a simple description is first provided for a legacy system that includes a legacy contents provider terminal device and playback device, after which a description is provided for the contents provider terminal device in the present embodiment.

2.1 Structure of Legacy Contents Provider Terminal Device 112, Playback Device 114

The structure of a legacy contents provider terminal device 112 differs from the structure of a contents provider terminal device 102 in that 1) the legacy contents provider terminal device 112 is not provided with a transmission unit 502 and a signature information storage unit 510, and 2) operations of the processing unit (hereinafter, processing unit 2314) in the legacy contents provider terminal device 112 differ from the operations of the processing unit 514 in the contents provider terminal device 102. Otherwise, the structures are the same.

The processing unit 2314 uses key configuration information stored as additional information in the key configuration information storage unit 509.

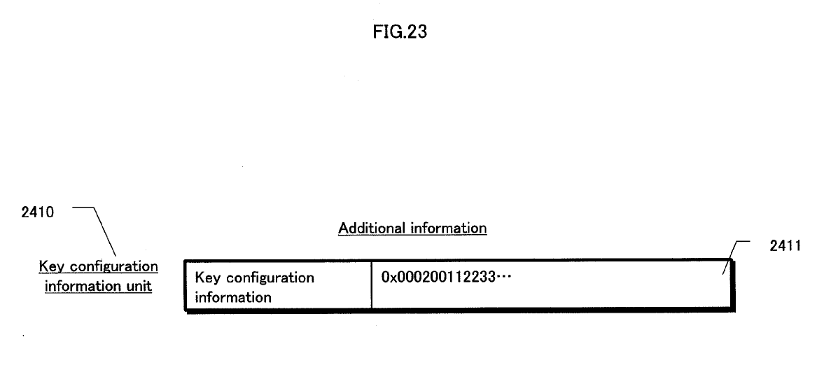

FIG. 23 shows an example of legacy additional information.

This additional information consists of a key configuration information unit 2410.

Due to the structural differences between the contents provider terminal device 102 and the legacy contents provider terminal device 112, the generated recording medium also differs.

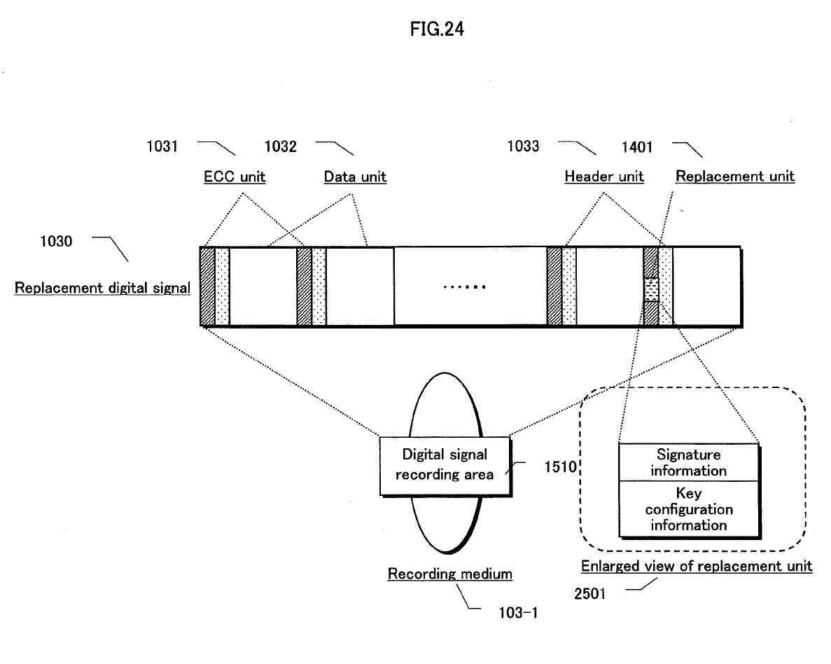

FIG. 24 shows a new system recording medium 103-1 produced by the contents provider terminal device 102.

As shown in FIG. 24, the additional information in the replacement unit is recorded in the order of signature information and key configuration information, unlike FIG. 12.

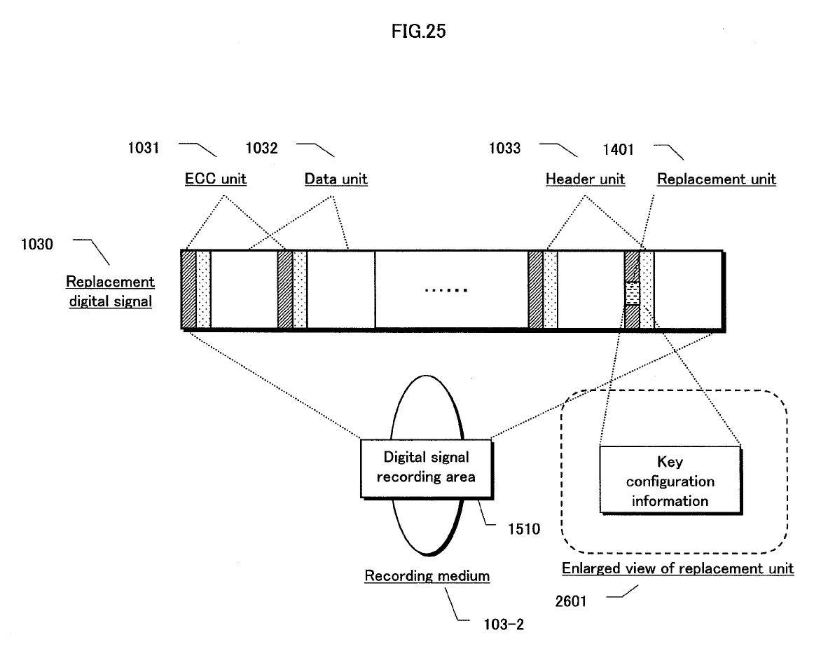

FIG. 25 shows a legacy recording medium 103-2 produced by the legacy contents provider terminal device 112.

In the replacement unit in the recording medium 103-1, signature information and key configuration information are recorded, and in the replacement unit in the recording medium 103-2, key configuration information is recorded.

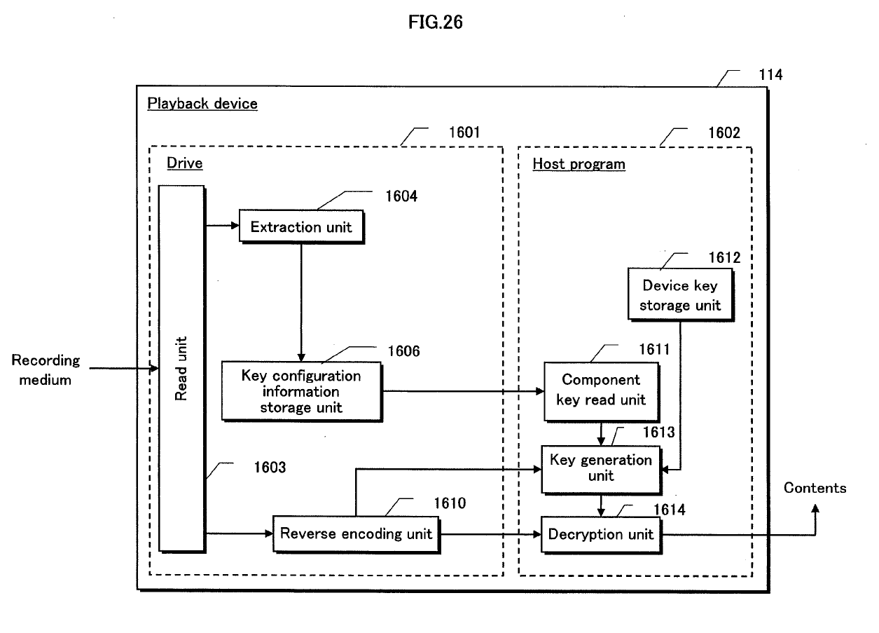

The structural differences between a legacy playback unit 114 and the playback unit 104 are that the legacy playback unit 114, as shown in FIG. 26, is not provided with the analysis unit 1605, certificate authority public key storage unit 1607, signature verification unit 1608, and providing unit 1609. Otherwise, the structures are the same.

2.2 Operations when the Legacy Playback Device 114 Plays Back the Recording Medium 103-1

In this case, as described below, the playback device 114 is ultimately unable to play back contents.

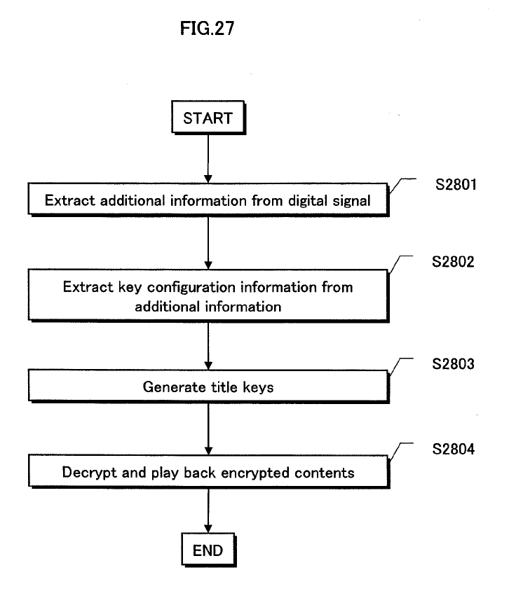

FIG. 27 shows the processing flow for playback operation of a recording medium by the legacy playback device 114.

First, the read unit 1603 reads a digital signal from the recording medium 103-1. The extraction unit 1604 extracts additional information from the read digital signal (step S2801). Next, the key configuration information storage unit 1606 records the additional information as is as key configuration information. The component key read unit 1611 requests a component key from the key configuration information storage unit 1606. The key configuration information storage unit 1606 attempts to return the section corresponding to the component key within the recorded key configuration information. If, unlike the legacy system, the additional information is positioned in the order of a signature information unit 1210 and a key configuration unit 1220 as shown in FIG. 12, then at this point, the key configuration information storage unit 1606 ends up reading part of the signature information unit 1310 at the top of the additional information as the key configuration information (step S2802). In this case, the key configuration information storage unit 1606 returns an incorrect component key to the component key read unit 1611.

Next, the key generation unit 1613 calculates the media key value, using the device key and the media key output by the reverse encoding unit 1610, and then calculates the key for the title key using the media key value and the component key. Furthermore, the key generation unit 1613 decrypts encrypted title keys in the encrypted title key information output by the reverse encoding unit 1610, thus calculating the title key.

Since the component key is incorrect, however, the value for the title key also ends up being incorrect (step S2803). Next, the encrypted contents output by the reverse encoding unit 1610 are decrypted using the calculated title key, but as the encrypted contents are not decrypted correctly, the contents cannot be played back (step S2804).

As described above, with a structure wherein the position of key configuration information does not match the additional information for a legacy system as shown in FIG. 23, such as when additional information is defined as shown in FIG. 24, then contents cannot be played back correctly. Conversely, with a structure wherein the position of key configuration information matches the additional information for a legacy system as shown in FIG. 23, such as when additional information is defined as shown in FIG. 13, then even if signature verification is not performed, contents can be played back correctly.

In other words, depending on the definition of newly defined additional information (an example of which is the order of the signature information and key configuration information), it is possible to change whether or not a legacy playback device can play back contents recorded on the recording medium 103-1.

In the case where the component key is incorrect and playback is not possible, when error processing by the playback device 114 is not properly implemented, then the playback device 114 may malfunction, e.g. by freezing, rebooting, or breaking.

To address the above-described problem, it is possible to record, on the recording medium 103, information that identifies whether the recording medium was constructed under the legacy system or the new system. It is preferable to furnish the playback device 114 with a protection function for the playback device 114 to identify the identification information and accordingly, when the recording medium 103-1 is identified, at that point (i) automatically eject the disc or only accept a command to eject the disc, and (ii) display a message that playback of the recording medium is not supported. For example, the identification information can be defined in the reserved area in an application's basic file (specifically, a single file existing on the recording medium 103, in which information defining the configuration of the application layer is written). A description is provided below for a contents provider terminal device that generates a recording medium that has, written thereon, information identifying whether the recording medium was constructed under the legacy system or the new system.

2.3 Operations when the Playback Device 104 Plays Back the Legacy Recording Medium 103-2

Operations when the playback device 104 plays back the legacy recording, medium 103-2 are now described with reference to FIG. 21.

In this case as well, as described below, the playback 104 is ultimately unable to play back contents.

First, the read unit 1603 reads a digital signal from the recording medium 103-2. The extraction unit 1604 then extracts additional information from the read digital signal. At this point, the playback device 104, which expects the additional information to be as in FIG. 12, extracts what it mistakes as key confirmation information and signature information from the read data, since there is actually only key configuration information in the additional information (step S2201).

Next, the analysis unit 1605 separates the key configuration information and signature information from the additional information (step S2202). Since signature information does not actually exist in the additional information, the signature information that is separated in this step is an irrelevant, incorrect value.

Next, the signature verification unit 1608 receives the key configuration information and signature information from the analysis unit 1605 and performs signature verification on the key configuration information using the signature in the signature information. Since the signature information itself is incorrect, however, the signature verification fails (step S2203). Since signature verification fails, processing proceeds to step S2204. Next, the key component read unit 1611 in the host program 1602 requests the component key information from the drive 1601. In this case, the providing unit 1609 in the drive 1601 does not provide the component key and, for example, responds to the request for component key information with an error. Receiving these results, the host program 1602 stops playback of the corresponding disc. Then the playback device notifies the user that playback is not possible by a method such as only accepting a command to eject the disc and displaying a panel on-screen indicating that the disc is unauthorized (step S2204).

In the above-described way, when the playback device 104 plays back the legacy recording medium 103-2 to which a signature is not added, at least signature verification fails, and thus playback stops.

2.4 Summary of Whether Playback of Contents is Possible for Combinations of the Systems and Recording Media

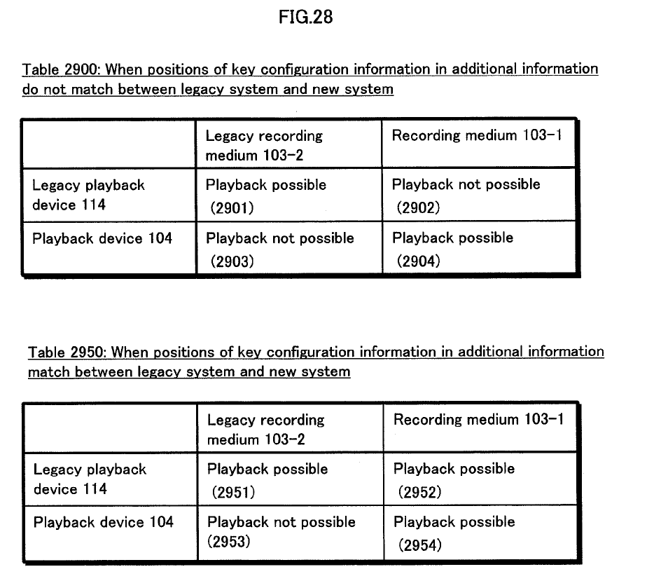

FIG. 28 shows tables summarizing whether playback is possible based on combinations of a playback device and a recording medium.

As described above, the recording location of key configuration information in the additional information changes whether the legacy playback device 114 and playback device 104 can play back the recording medium 103-1 and recording medium 103-2.

Table 2900 summarizes whether playback is possible when the positions of the key configuration information in the additional information do not match between the legacy system and the system in the above-described embodiment (hereinafter, “new system”).

The legacy recording medium 103-2 can be played back by the legacy playback device 114, but not by the playback device 104. Conversely, the recording medium 103-1 cannot be played back by the legacy playback device 114, but can be played back by the playback device 104.

Table 2905 summarizes whether playback is possible when the positions of the key configuration information in the additional information match between the legacy system and the new system.

The legacy recording medium 103-2 can be played back by the legacy playback device 114, but not by the playback device 104. Conversely, the recording medium 103-1 can be played back by both the legacy playback device 114 and the playback device 104. As indicated in entries 2902 and 2952, whether playback by the legacy playback device is possible depends on whether the positions of the key configuration information in the additional information match or not between the existing system and the new system.

By recording on the recording medium 103-1, as identification information, which configuration the additional information adopts, it is therefore possible to notify the legacy playback device 114 of whether or not it can play back the recording medium 103-1.

Note that in other patterns, operations are possible or not regardless of the position of the key configuration information in the additional information. In these cases, it is considered that there will be no confusion even if no particular distinction is made via identification information. In these other patterns, however, identification information can be used to indicate which configuration the additional information adopts and to indicate whether the recording medium was created under the legacy or new system.

2.5 Contents Provider Terminal Device 122

An explanation is provided for a contents provider terminal device 122 that can create both the legacy recording medium 103-2 and the new system recording medium 103-1.

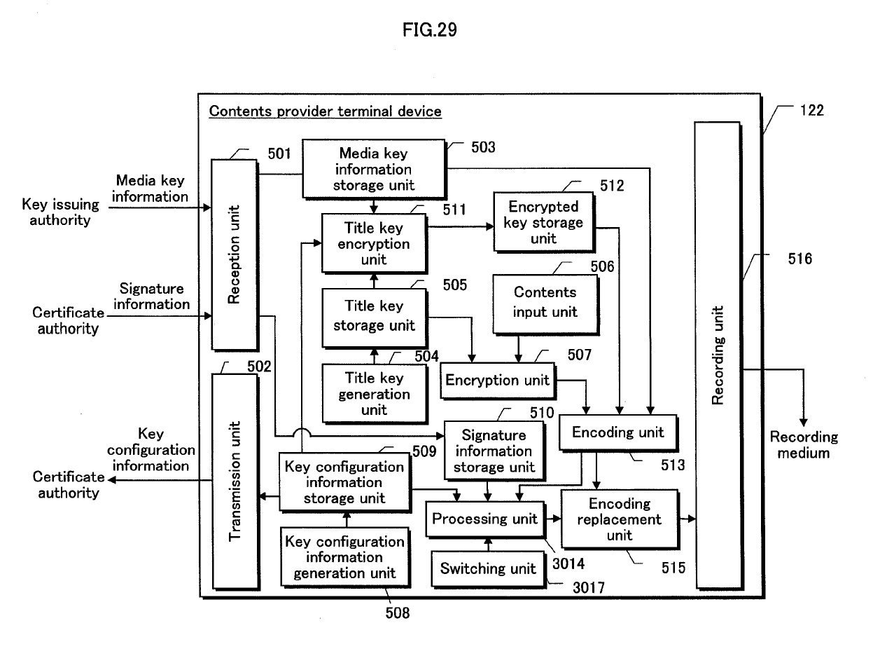

As shown in FIG. 29, the contents provider terminal device 122 is the contents provider terminal device 102 with the addition of a switching unit 3017.

The switching unit 3017 accepts, via user input, a selection to create a recording medium for the legacy system or a recording medium for the new system. The switching unit 3017 records the user input and commands the processing unit 3014 to generate additional information.

The processing unit 3014 outputs additional information for legacy use when the command from the switching unit is to create a legacy recording medium and additional information for new system use when the command is to create a new system recording medium.

With this structure, the contents provider terminal device 122 can manufacture both the legacy recording medium 103-2 and the recording medium 103-1.

### 3. Embodiment 3

3.1 Outline

In the above-described embodiments, by specification, identification information and signature information unique to a recording medium were recorded in an area in the recorded data on the recording medium (hereinafter, “first area”) that is not output to a device external to the drive. Therefore, if the data recorded on the recording medium is copied by being read by a standard drive and then writing the read data on a new recording medium, the data recorded in the first area would not be read, as a result making it possible to prevent the entire contents of the recording medium from being copied.

However, the manufacture and sale of a drive that outputs a digital signal before reverse encoding as is to a host program are plausible. When writing a digital signal as is on the recording medium 103, to achieve mass production in a short period of time, a model called a stamper is created in order to write an analog signal in which a digital signal defined by 0's and 1's has been converted to analog. A stamper is used to mass-manufacture recording media similar to block printing. By connecting, for example, a drive that outputs this kind of digital signal as is to a PC, reading the digital signal from the recording medium, and copying it to another recording medium, a recording medium can be created with the replacement section of the ECC unit 1031 intact (i.e. including the additional information). The problem then occurs that the contents on this recording medium can be played back by a commercial playback device.

In order to prevent the creation of an unauthorized copy wherein, as described above, the entire contents of the recording medium are copied using a drive that outputs the digital signal before reverse encoding as is to the host program, there is a method for embedding information necessary for playback, such as the ROM mark used in a BD, in a second area as an analog signal. By writing a special pit that is difficult to process on the master recording medium (second area), a ROM Mark prevents copying of a recording medium via unauthorized mastering. When playing back the recording medium, reading of data is permitted only when a characteristic signal is detected in the ROM Mark in the analog signal read by the optical head in the drive.

The information embedded in the analog signal is lost when the read unit 1603 reads the analog signal from the recording medium 103 and converts it to a digital signal. Information necessary for decrypting the contents, e.g. key configuration information and component keys, are embedded in the analog signal. The method for converting an analog signal to a digital signal is widely known, but the method for extracting information embedded in the analog signal is not public. That is, in general this method is a completely unknown technology; even drive manufacturers merely purchase, from the company that has developed this method, the program and hardware to extract information embedded in the analog signal. The drive manufacturers then include the program and hardware on drives without ever learning the method. Therefore, a special drive that outputs the analog signal as is cannot be created. Accordingly, it can be said that the method for embedding information in an analog signal is more secure than the method that replaces part of the ECC unit 1031.

However, the development of recording media that have this sort of second area requires a considerable amount of time, as does replacing drives that only support the first area, which are already commercially available, with drives that support the second area. As long as both types of drives exist, a recording medium that is compatible for playback on both a legacy drive and a new drive is preferable. The following is an explanation of a structure to implement such compatibility. Note that explanation is omitted for structural elements and the like that are the same as the above-described embodiments.

3.2 Structure

3.2.1 Structure of Contents Provider Terminal Device 142

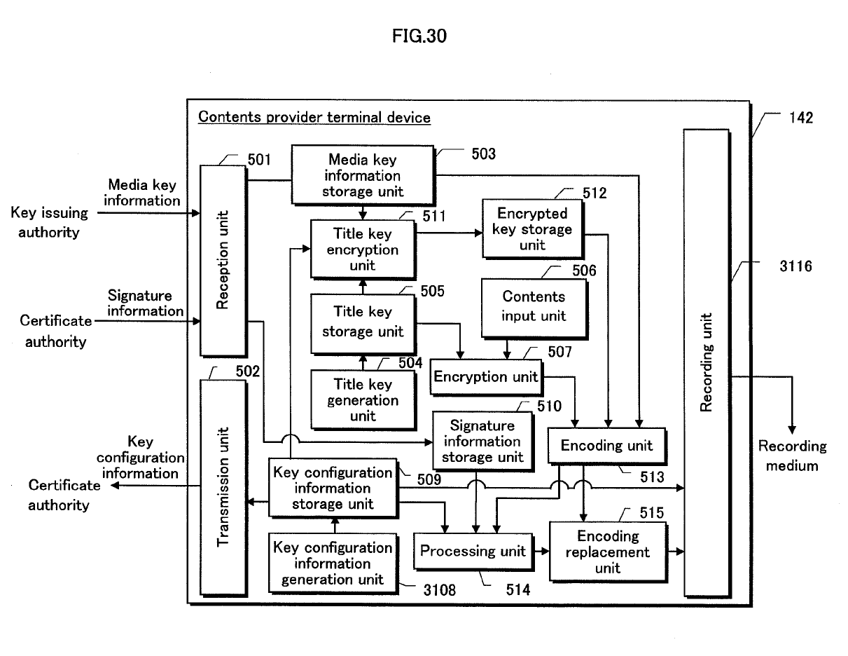

FIG. 30 is a block diagram showing the structure of a contents provider terminal device 142.

As compared to the contents provider terminal device 102, the structures of the key configuration information generation unit 3108 and the recording unit 3116 in the contents provider terminal device 142 differ. The following is an explanation of the differences.

(1) Key Configuration Information Generation Unit 3108

The key configuration information generation unit 3108 generates key configuration information that includes component keys used for calculation of the keys for the title keys, which encrypt title keys in the title key information.

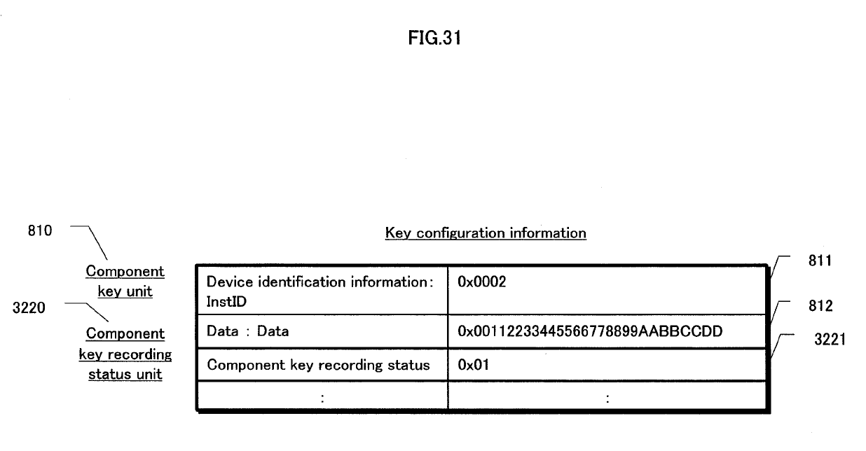

FIG. 31 shows an example of key configuration information.

The key configuration information has a component key unit 810 and a component key recording status unit 3220.

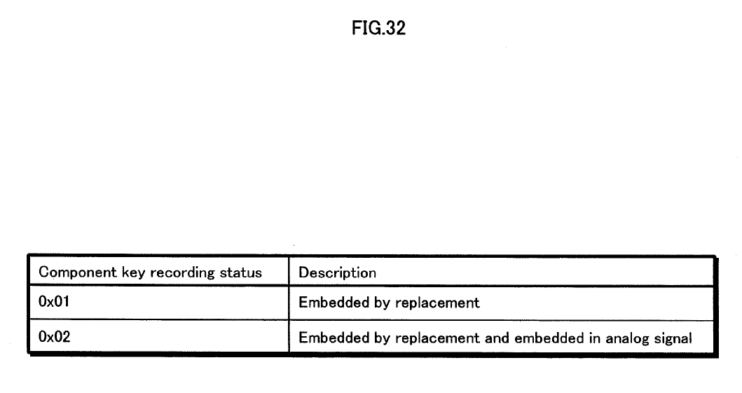

The device identification information field 811 in the component key unit 810 is a fixed value assigned to each key configuration information embedding system distributed to contents providers. In the case of FIG. 31, the InstID is 0x0002, indicating use of the key configuration information embedding system to which 2 is assigned as the value of the identification information. An arbitrary value is assigned to the data field 812. The component key recording status is information indicating how the component key is embedded, e.g. embedded by replacement in the digital signal, embedded in the analog signal, etc. FIG. 32 shows an example of a definition of the component key recording status. 0x01 means that the component key is embedded by replacement in the ECC unit 1031, and 0x02 means that the component key is embedded both by replacement in the ECC unit 1031 and by being embedded in the analog signal.

(2) Recording Unit 3116

The recording unit 3116 receives a replacement digital signal from the encoding replacement unit 515. The recording unit 3116 also receives key configuration information from the key configuration information storage unit 509. The recording unit 3116 embeds the component keys in the analog signal generated from the replacement digital signal and uses the analog signal with the component keys embedded therein to manufacture the recording medium 103.

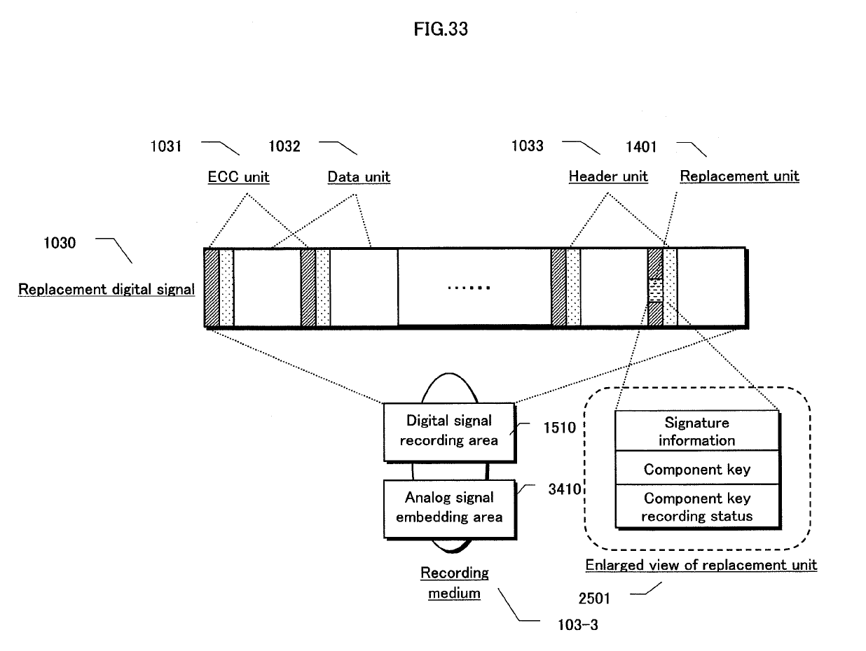

FIG. 33 shows an example of a recording medium manufactured using an analog signal with component keys embedded therein. A recording medium 103-3 is composed of a digital signal recording area 1510 and an analog signal embedding area 3410. The analog signal embedding area 3410 is embedded in the analog signal created from the recorded digital signal. The analog signal embedding area 3410 exists at the same physical location as where the digital signal is recorded on the recording medium 103-3, which is manufactured using this analog signal. In FIG. 33, however, the analog signal embedding area 3410 is depicted as an explicitly different area.

The important characteristic of the present embodiment is that the component keys are placed in a different location than the replacement unit 1401 and with a different method. As long as this characteristic is maintained, the location where the component keys are placed can be either the same physical location as where the digital signal is recorded or a different location.

3.2.2 Structure of a Playback Device 144

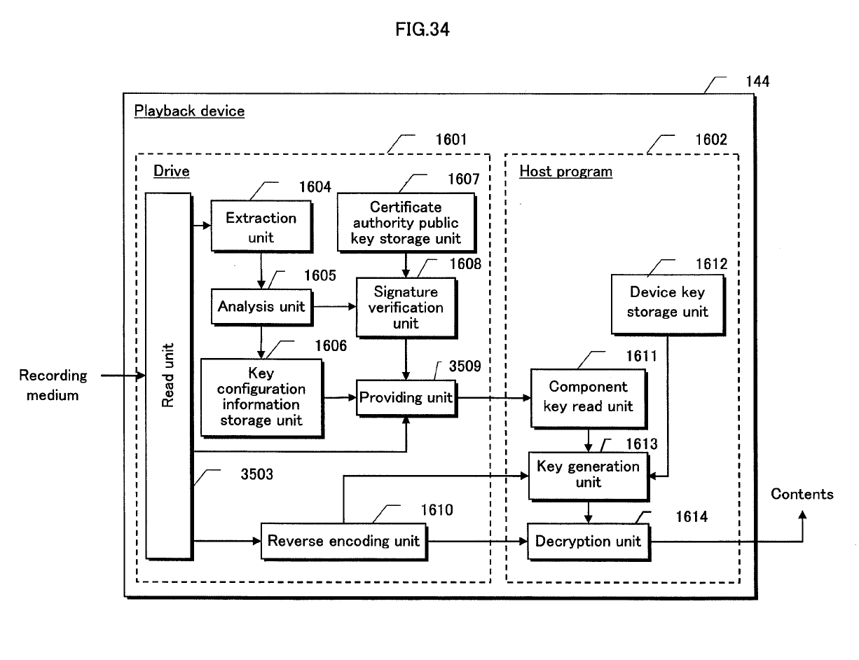

Next, the details regarding the structure of the playback device 144 are provided with reference to FIG. 34.

The functions of the read unit 1603 and the providing unit 1609 in the playback device 104 have been changed, and these units are labeled read unit 3503 and providing unit 3509 in the playback device 144.

The read unit 3503 both reads a digital signal from the recording medium 103 and also reads the information embedded in the analog signal embedding area 3410 from the recording medium 103.

When the providing unit 3509 receives a request for component keys from the component key read unit 1611, if the signature verification results output by the signature verification unit 1608 indicate success, the providing unit 3509 also acquires the component key recording status.

If the component key recording status is 0x01, the providing unit 3509 provides the component key read unit 1611 with component keys in the key configuration information stored by the key configuration information storage unit 1606. If the component key recording status is 0x02, the providing unit 3509 provides the component key read unit 1611 with component keys in the key configuration information read by the read unit 3503.

If the signature verification results output by the signature verification unit 1608 indicate failure, the providing unit 3509 does not provide the component key read unit 1611 with component keys in the key configuration information stored by the key configuration information storage unit 1606.

Accordingly, as in the above embodiments, the host program 1602 is not notified of the component keys, and playback of contents by the host program 1602 can be stopped.

### 4. Other Modifications

The present invention was described based on the above embodiments, but of course the present invention is not limited to the above embodiments. The present invention also includes the following cases.

(1) In the above embodiments, a structure wherein component keys are written in additional information is described, but keys other than component keys, such as title keys, may also be written therein. Furthermore, keys may be disc identification numbers used to decrypt contents.

(2) In the above embodiments, a signature is issued in an identifying bit indicating the recording medium's identification information and the recording status of the identification information. However, one signature may be issued for data that combines the identification information and identifying bit, or one signature may be issued for each of the identification information and the identifying bit.

(3) The recording medium is not limited to read-only media, but may also be another form of media. For example, the recording medium may be a writeable form of media, such as recordable media, rewritable media, etc.

(4) In the above embodiments, examples are provided for structures that adopted two methods: an embedding method to replace part of the ECC unit 1031, and a method to embed information in an analog signal. The present invention may be implemented, however, replacing either one or both of these methods with a different method. For example, there are embedding methods other than replacing part of the ECC unit 1031 or embedding information in an analog signal, such as: a method to write on the Burst Cutting Area (BCA); a method to record on the recording medium, along with the contents, a file with identification information; etc.

(5) In the above embodiments, examples are provided for structures that adopted two methods: an embedding method to replace part of the ECC unit 1031, and a method to embed information in an analog signal. Three or more methods, however, may be used.

(6) In the above embodiments, examples are provided for structures in which the processing unit 514 in the contents provider terminal device 102 (i) stored arbitrary identification information as is in the component key unit 810 in the key configuration in the additional information, and (ii) performed XOR on the top 128 bits of the signature. The following structure, however, may be adopted. Apart from the certificate authority public key/private key stored by the certificate authority terminal device 101, a contents provider public key/private key is generated for each contents provider terminal device 102, the contents provider private key is issued to the contents provider terminal device 102, and the contents provider public key is issued to the playback device 104. In the contents provider terminal device 102, the value of the component key unit 810 is encrypted with the contents provider private key and overwritten in the additional information. Conversely, the drive 1601 in the playback device 104 decrypts and reads the value of the component key unit 810 in the extracted additional information using the contents provider public key. In this case, considering the emergence of new contents providers in the future, a plurality of pairs of contents provider public keys/private keys are generated, for example 256 pairs, and 256 public keys are pre-issued to the playback device 104. In addition to the component key unit 810, contents provider identification information is made to be recordable in the key configuration information. The drive 1601 in the playback device 104 recognizes the contents provider identification information in the key component information and determines which of the 256 contents provider public keys to use to decrypt the component keys. With the above-described structure, an unauthorized drive that does not have the contents provider public key cannot properly read the component keys, and therefore cannot play back the contents. Only an authorized drive can properly read the component keys and play back the contents.

(7) In the above embodiments, the contents provider terminal device 102 transmits the key configuration information to the certificate authority terminal device 101, and the certificate authority terminal device 101 generates signature information from the key configuration information. The information serving as the source for generating signature information, however, is not limited to the key configuration information, and may be any piece of information that can verify the authenticity of the key configuration information. For example, a structure may be adopted wherein, instead of the key configuration information, the contents provider terminal device 102 transmits a hash value for the key configuration information, and the certificate authority terminal device 101 generates a signature for the received hash value to generate signature information.

(8) In the above embodiments, the certificate authority public key/private key generation unit 204 in the certificate authority terminal device 101 generates a public key and a private key. The device that generates the public key and private key, however, does not need to be the same as the device that performs certification, and a method may be adopted wherein a completely different device generates and inputs the public key and private key.

(9) In the above embodiments, the processing unit 514 in the contents provider terminal device 102 constructs additional information from key configuration information 1211 and signature information 1212, but the present invention is not limited in this way. Additional information may be constructed after applying bit inversion or the like to the key configuration information 1211 and signature information 1212.

For example, a structure may be adopted wherein bit inverted key configuration information, which is the key configuration information 1211 after being bit inverted, is recorded in the key configuration information unit 1210. Furthermore, a structure may be adopted wherein, for example, the results of performing calculation such as XOR on the value of the key configuration information are overwritten on the top of the signature information 1212, e.g. the value of the top 128 bits of the signature information unit when the key configuration information is 128 bits.

Note that, when adopting a structure that uses bit inversion or a structure that uses XOR, simply reading from the key configuration unit 1210 will result in reading incorrect key configuration information.

(10) In FIG. 15, the playback device consists of a hardware implemented drive 1601 and a program 1602. The program 1602 may also, however, be hardware implemented.

(11) In the above embodiments, the title key generation unit 504 generates title keys, but the present invention is not limited in this way. The title keys may also be input from outside of the playback device.

(12) In the above embodiments, the key configuration information generation unit 508 generates key configuration information, but the present invention is not limited in this way. For example, key configuration information may be generated by a different terminal device. A method may also be adopted wherein an operator inputs an arbitrarily conceived value into the contents provider terminal device 102. Furthermore, a method may be adopted wherein the contents provider terminal device 102 automatically generates a value.

Note that, apart from the above-described example in which the component keys consist of the InstID and data fields, the component keys may be (i) identification information for the recording device used for calculation of the keys for the title keys, (ii) stamper identification information as described below, etc.

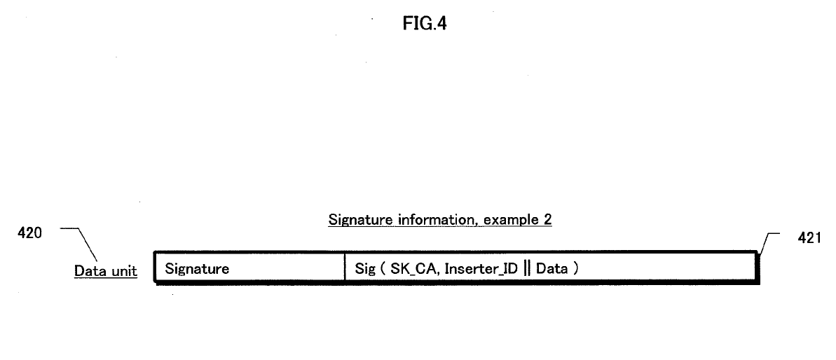

(13) In the above embodiments, in the signature generation unit 203, a hash value is calculated from the entire key configuration information, but the present invention is not limited in this way, as long as information that can identify the key configuration information is used. For example, part of the key configuration information may be used for calculation of the hash value. Also, in the above embodiments, the signature information shown in FIG. 3 is used, but the present invention is not limited in this way; the signature information shown in FIG. 4 may also be used. In the case of FIG. 4, the signature information consists of a data unit 420, and the data unit 420 has a signature field 421. The generated signature is written in the signature field 421.

(14) In the above embodiments, as shown in FIG. 12, the key configuration information unit 1210 and signature information unit 1220 are stored in that order in the additional information, but the present invention is not limited in this way; the signature information unit 1220 may be stored before the key configuration information unit 1210.

(15) Supplemental Explanation for Error Correction Processing

The drive 1601 that reads a digital signal from the recording medium 103 performs error correction out of consideration for read errors. So that this error correction processing will not fall behind the playback processing by the host program 1602, each function block constituting the drive 1601 may be hardware implemented. In particular, a software implementation of the reverse encoding unit has the following adverse effects: as compared to playback processing for video and audio, the reverse encoding processing load is great, and thus reverse encoding takes time, causing a delay in the provision of data. This creates noise in the video and audio playback and causes jumps in the video and audio processing; therefore, a hardware implementation is preferable.

From the standpoint of improved security, it is preferable to implement the reverse encoding unit, signature verification unit, and providing unit by hardware. Also, if possible, it is even better to implement the read unit 1603, extraction unit 1604, analysis unit 1605, key configuration information storage unit 1606, certificate authority public key storage unit 1607, signature verification unit 1608, providing unit 1609, and reverse encoding unit 1610 by hardware. As compared to a PC player or the like, it is difficult to tamper with the processing of the drive 1601, and thus the functions implemented by the drive 1601 are generally more secure than when implemented by the host program 1602. Note that in the configuration in FIG. 15, the drive is included in the playback device, but it may also be an attached drive external to the playback device. Furthermore, it is not necessary to implement each function block shown in FIG. 15 separately by hardware; a plurality of function blocks may be grouped together and implemented as one piece of hardware. To offer even stronger protection in a hardware implementation, the hardware may additionally be provided with tamper resistance. A variety of methods for providing hardware with tamper resistance are widely known, and thus an explanation thereof is omitted.

(16) In the above embodiment, the key configuration information generation unit 3108 generates the key configuration information, but the present invention is not limited in this way. A different terminal device may generate this information, or a method may be adopted wherein an operator inputs an arbitrarily conceived value into the contents provider terminal device 142, or wherein the contents provider terminal device 142 automatically generates a value.

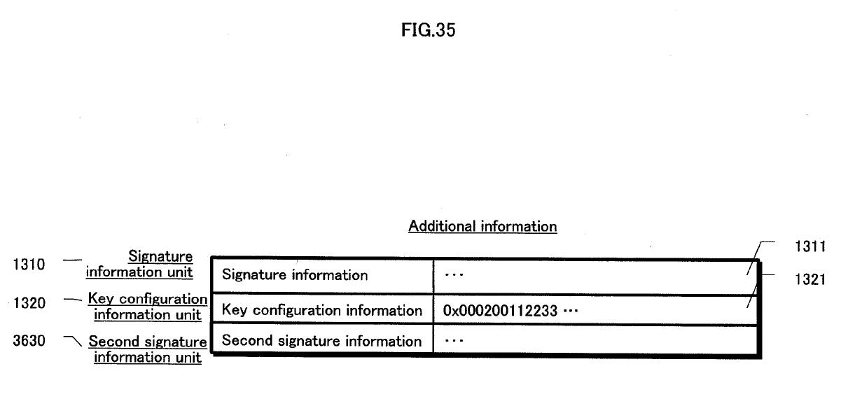

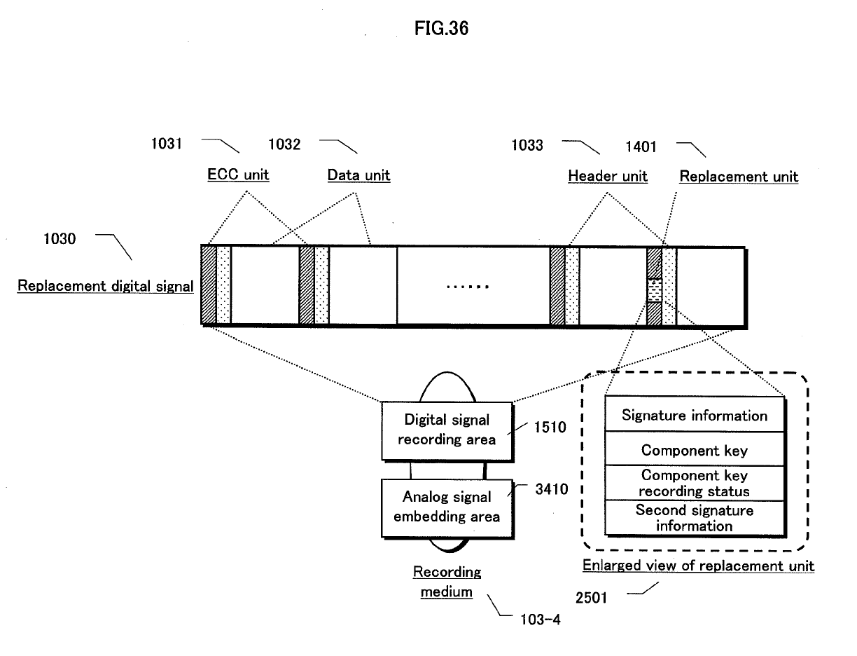

(17) In the above embodiments, a structure to embed component keys in an analog signal was described with reference to FIG. 33, but either the key configuration information or other information may be embedded. For example, each time a stamper is generated, a unique value may be defined and embedded as stamper identification information. When embedding stamper identification information, in order to address the problem of unauthorized copying of the digital signal before reverse encoding, second signature information may be generated for the stamper identification information and added to the additional information. FIG. 35 shows an example of additional information to which second signature information has been added. FIG. 36 shows an example of a recording medium 103-4 that has the additional information shown in FIG. 35.

When the recording medium 103-4 is played back by the playback device 144, if the providing unit 3509 detects the existence of second signature information, it receives, from the read unit 3503, the information embedded in the analog signal embedding area 3410, which is stamper identification information. Then, using the stamper identification information and the second signature information, signature verification is performed, and a determination is made as to whether the verification succeeds or fails. When signature verification fails, the providing unit 3509 does not provide the component key read unit 1611 with the component keys. As a result, the playback device 144 cannot correctly play back the contents.

(18) The present invention may be a recording medium used together with a playback device for decrypting and playing back encrypted contents, wherein the playback device, when acquiring a key used to decrypt the encrypted contents, acquires the key from a first area on the recording medium, and the recording medium (i) has the key used to decrypt the encrypted contents recorded in a second area differing from the first area and (ii) has information recorded thereon to notify the playback device that the key is not recorded in the first recording area.

With the above-described structure, the playback device can be notified that it cannot acquire the key from the first area when such is the case.

The recording medium is further used by a second playback device that, when acquiring a key used to decrypt the encrypted contents, acquires the key from the second area in the recording medium and verifies the key, and the recording medium has information, used to verify authenticity of the key, recorded in the first area.

With the above-described structure, information used to verify the key is recorded in the first area, where the key was originally stored; therefore, there is no need to provide a separate area for recording this information on the recording medium. Accordingly, a reduction in the recording medium's capacity can be mitigated.

Furthermore, the identification information for the recording medium is embedded in a digital signal that is recorded so that the identification information is lost when read by a standard drive. This recording area is defined as the first area. However, there are special drives that can output a digital signal as is, before the identification information for the recording medium is lost. By using this special drive to copy the entire contents of the recording medium, including the embedded identification information for the recording medium, an unauthorized copy playable on a commercial player can be made. To prevent unauthorized copying by a special drive, a recording medium on which identification information for the recording medium is recorded in a second area that cannot be read when making a special copy is necessary. As it takes a considerable amount of time, however, to replace already commercially available drives that only support the first area with drives that support the second area, a recording medium that addresses the above-mentioned first problem will be in general use for some time. Afterwards, recording media that have their identification information recorded in a second area will appear on the market. Thus, when recording media that only support the first area and recording media that support the second area both exist, a second problem emerges in that both legacy drives and new drives need to be able to play back both types of recording media.

In order to solve the first problem, the recording system for a recording medium according to the present invention does not simply record identification information on the recording medium as the identification information for the recording medium. Rather, a third party issues a signature for the identification information, and the signature is recorded on the recording medium in combination with the identification information. Conversely, when signature verification using the identification information and the signature recorded on the recording medium succeeds, a playback device plays back the contents, whereas when the verification fails, it stops playback of the contents.

To solve the above-mentioned second problem as well, a recording system for a recording medium according to the present invention records identification information for the recording medium in an area that even a special drive does not output to an external device and writes, in the first area, an identifying bit indicating whether the identification information for the recording medium is recorded only in the first area or is recorded in both the first area and the second area. A third party issues a signature for the identification information for the recording medium and the identifying bit, and records the signature in the first area in the recording medium. When signature verification fails, the drive stops playback, and when signature verification succeeds, the drive reads identification information for the recording medium in accordance with the identifying bit.

With the above-described structure, even if an unauthorized individual uses non-authentically acquired contents to manufacture a recording medium such as a BD or DVD, the unauthorized individual cannot acquire the signature for the identification information for the recording medium, and thus cannot create an unauthorized copy playable by a commercial player.

Also, by introducing an identification bit, a drive that supports the second area can read identification information from the first or second area in accordance with the identifying bit, and a drive that does not support the second area can consistently read identification information from the first area. In this way, both drives can play back an authentic recording medium. At the same time, even if the contents of a recording medium are copied entirely, the information that needs to be recorded in the second area cannot be recorded, and thus creation of an unauthorized copy can be prevented.

(19) Each of the above devices is, specifically, a computer system that includes a microprocessor, ROM, RAM, hard disk unit, display unit, keyboard, mouse, etc. Computer programs are stored on the RAM or hard disk unit. The microprocessor operates in accordance with the computer programs, and each device thereby fulfills its functions. These computer programs are composed of a plurality of command codes that indicate instructions for the computer in order to fulfill specific functions.

Note that each device is not limited to a computer system that includes all of the following components: a microprocessor, ROM, RAM, hard disk unit, display unit, keyboard, mouse, etc. Each device may be a computer system including only some of these components.

(20) Part or all of the components in each of the above-described devices may be assembled as one system Large Scale Integration (LSI). A system LSI is an ultra-multifunctional LSI produced by integrating multiple components on one chip and, more specifically, is a computer system including a microprocessor, ROM, RAM, and the like. Computer programs are stored in the RAM. The microprocessor operates according to the computer programs, and thereby the system LSI accomplishes its functions. Individual components may respectively be made into discrete chips, or part or all of the components may be made into one chip.

Although referred to here as an LSI system, depending on the degree of integration, the terms IC, system LSI, super LSI, or ultra LSI are used.

In addition, the method for assembling integrated circuits is not limited to LSI, and a dedicated communication circuit or a general-purpose processor may be used. A Field Programmable Gate Array (FPGA), which is programmable after the LSI is manufactured, or a reconfigurable processor, which allows reconfiguration of the connection and setting of circuit cells inside the LSI, may be used.

Furthermore, if technology for forming integrated circuits that replaces LSIs emerges, owing to advances in semiconductor technology or to another derivative technology, the integration of functional blocks may naturally be accomplished using such technology. The application of biotechnology or the like is possible.

(21) Part or all of the components making up each of the above devices may be assembled as an IC card detachable from each device, or as a single module. The IC card/module is a computer system that includes a microprocessor, ROM, RAM, etc. The IC card/module may include therein the above-mentioned ultra-multifunctional LSI. The microprocessor operates according to computer programs, and the IC card/module thereby accomplishes its functions. The IC card/module may be tamper resistant.

(22) The present invention may be a method of accomplishing the above-described system. The present invention may be computer programs that achieve the method by a computer, or may be a digital signal comprising the computer programs.

The present invention may also be achieved by a computer-readable recording medium, such as a flexible disk, hard disk, CD-ROM, MO, DVD, DVD-ROM, DVD-RAM, BD, or semiconductor memory, on which the above-mentioned computer program or digital signal is recorded. The present invention may also be the computer programs or the digital signal recorded on such a recording medium.

The present invention may also be the computer programs or digital signal to be transmitted via networks, of which telecommunications networks, wire/wireless communications networks, and the Internet are representative, or via data broadcasting.

Also, another, independent computer system may implement the computer programs or digital signal after the computer programs or digital signal is transferred via being recorded on the recording medium, via one of the above-mentioned networks, etc.

(23) The above embodiments and modifications may be combined with one another.

### INDUSTRIAL APPLICABILITY

The present invention is useful in devices and systems that handle digital contents that require copyright protection and can be used by companies that manufacture and sell devices that play back and record digital contents, and by companies that construct and sell such systems.

### REFERENCE SIGNS LIST

101 Certificate authority terminal device
102 Contents provider terminal device
103 Recording medium
104 Playback device
105 Key issuing authority terminal device

1. A drive device for reading encrypted contents from a recording medium and outputting the encrypted contents to a host device, the drive device comprising:
a read unit operable, when the host device issues an acquisition request for generation information used to generate a decryption key for an encrypted content, to read both the generation information and a digital signature, which is created using the generation information and a signing key, from a control area in the recording medium, restricting the digital signature for use only within the drive device, the control area being specified to have control information used only within the drive device;
a verification unit operable to verify authenticity of the generation information using the digital signature; and
an output control unit operable to output the generation information to the host device only when the generation information is judged to be authentic.

2. The drive device in claim 1, wherein
the control area is specified to have an error correction code for data in a data recording area in the recording medium therein,
the generation information and the digital signature are recorded in a specific area in the control area, and
the read unit reads the generation information and the digital signature from the specific area.

3. The drive device in claim 2, wherein
invalid data is written in an area located within the data recording area and corresponding to the specific area, and
the read unit (i) does not read the invalid data, (ii) performs error correction when reading data recorded in the data recording area other than the invalid data, and (iii) does not perform error correction when reading the generation information and the digital signature.

4. The drive device in claim 1, wherein
the verification unit and the output control unit are implemented only by hardware.

5. The drive device in claim 1, wherein
condition identification information that identifies a first writing condition and a second writing condition is recorded on the recording medium, the first writing condition indicating that the generation information is positioned before the digital signature in the control area, and the second writing condition indicating that the digital signature is positioned before the generation information, and
the read unit reads the condition identification information before reading the generation information and the digital signature, subsequently reading the generation information and the digital signature in accordance with the condition identification information.

6. The drive device in claim 1, wherein
condition identification information that identifies a first writing condition and a second writing condition is recorded on the recording medium, the first writing condition indicating that the generation information and the digital signature are written in the control area, and the second writing condition indicating that the generation information and the digital signature are written with analog technology instead of being written in the control area, and
the read unit reads the condition identification information before reading the generation information and the digital signature, subsequently reading the generation information and the digital signature in accordance with the condition identification information.

7. A contents playback device for reading encrypted contents from a recording medium and playing back the encrypted contents, the contents playback device comprising:
a drive unit operable to read information from the recording medium; and
a host unit operable to decrypt and play back an encrypted content using information acquired from the drive unit,
the drive unit comprising:
a read subunit operable, when the host unit issues an acquisition request for generation information used to generate a decryption key for the encrypted content, to read both the generation information and a digital signature, which is created using the generation information and a signing key, from a control area in the recording medium and to restrict the digital signature for use only within the drive unit, the control area being specified to have control information used only within the drive unit;
a verification subunit operable to verify authenticity of the generation information using the digital signature; and
an output control subunit operable to output the generation information to the host unit only when the generation information is judged to be authentic,
the host unit comprising:
a request subunit operable to issue the acquisition request to the read unit;
a key generation subunit operable, upon acquiring the generation information from the drive unit, to generate the decryption key using the generation information; and
a playback subunit operable to decrypt the encrypted content using the decryption key and play back the content.

8. The contents playback device in claim 7, wherein
at least the verification unit and the output control unit within the drive unit are implemented only by hardware.

9. A recording medium on which encrypted contents are recorded, wherein
generation information, used to generate a decryption key for an encrypted content, and a digital signature generated from the generation information are recorded in a control area, and
condition identification information that identifies a first writing condition and a second writing condition is recorded at a specific position in a control area, the control area being specified to have control information used only within a drive device that reads data from the recording medium, the first writing condition indicating that the generation information is positioned before the digital signature, and the second writing condition indicating that the digital signature is positioned before the generation information.

10. A recording device for recording encrypted contents on a recording medium, the recording device comprising:
an acquisition unit operable to acquire generation information, used to generate a decryption key for an encrypted content, and a digital signature generated from the generation information; and
a recording unit operable to record the generation information and the digital signature in a specific area on the recording medium, which has a data recording area and a control area in which an error correcting code for the data recorded on the data recording area is recorded, the specific area being within the control area, wherein
invalid data is written in an area located within the data recording area and corresponding to the specific area.

11. The recording device in claim 10, wherein
the acquisition unit includes:
a registration subunit operable to register input of the generation information used to generate a decryption key for the encrypted content;
a transmission subunit operable to transmit the generation information to a certificate authority device; and
a reception subunit operable to receive the digital signature generated by the certificate authority device for the generation information.

12. A data reading method, used in a drive device for reading encrypted contents from a recording medium and outputting the encrypted contents to a host device, the data reading method comprising the steps of:
reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device;
verifying authenticity of the generation information using the digital signature; and
outputting the generation information to the host device only when the generation information is judged to be authentic.

13. A data reading program, used in a drive device for reading encrypted contents from a recording medium and outputting the encrypted contents to a host device, the data reading program comprising the steps of:
reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device;
verifying authenticity of the generation information using the digital signature; and
outputting the generation information to the host device only when the generation information is judged to be authentic.

14. A computer readable recording medium storing a data reading program, used in a drive device for reading encrypted contents from a recording medium and outputting the encrypted contents to a host device, the data reading program comprising the steps of:
reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device;
verifying authenticity of the generation information using the digital signature; and
outputting the generation information to the host device only when the generation information is judged to be authentic.

15. An integrated circuit, used in a drive device for reading encrypted contents from a recording medium and outputting the encrypted contents to a host device, the integrated circuit comprising the steps of:
reading, when the host device issues an acquisition request for generation information used to generate a decryption key for an encrypted content, both the generation information and a digital signature, which is created using the generation information and a signing key, from a control area in the recording medium, restricting the digital signature for use only within the drive device, the control area being specified to have control information used only within the drive device;
verifying authenticity of the generation information using the digital signature; and
outputting the generation information to the host device only when the generation information is judged to be authentic.
